(19) United States
(12) Patent Application Publication
(10) Pub. No.: US 2023/0108276 A1
(43) Pub. Date: Apr. 6, 2023

(54) METHOD FOR PRODUCING LAMINATE AND TOUCH PANEL SENSOR

(71) Applicant: FUJIFILM Corporation, Tokyo (JP)

(72) Inventor: Hiroyuki YONEZAWA, Shizuoka (JP)

(73) Assignee: FUJIFILM Corporation, Tokyo (JP)

(21) Appl. No.: 18/060,375

(22) Filed: Nov. 30, 2022

Related U.S. Application Data
(63) Continuation of application No. PCT/JP2021/021049, filed on Jun. 2, 2021.

(30) Foreign Application Priority Data
Jun. 5, 2020 (JP) 2020-098776
Jul. 15, 2020 (JP) 2020-121631

(51) Int. Cl. G03F 7/20; G06F 3/041; G03F 7/09

(52) U.S. Cl. CPC G03F 7/2014; G06F 3/041; G03F 7/09

(57) ABSTRACT

Provided are a method for producing a laminate, including a step 1 of preparing a laminate precursor having a base material, a first transparent conductive portion, and a photosensitive composition layer in this order, a step 2 of pattern-exposing the photosensitive composition layer with scattered light from a side of the photosensitive composition layer opposite to a side on which the base material is provided, and a step 3 of developing the pattern-exposed photosensitive composition layer to form a patterned cured layer; and an application thereof.

### CROSS-REFERENCE TO RELATED APPLICATIONS

This application is a continuation application of International Application No. PCT/JP2021/021049, filed Jun. 2, 2021, which is incorporated herein by reference. Further, this application claims priority from Japanese Patent Application No. 2020-098776, filed Jun. 5, 2020, and Japanese Patent Application No. 2020-121631, filed Jul. 15, 2020, which are incorporated herein by reference.

### BACKGROUND OF THE INVENTION

### 1. Field of the Invention

The present disclosure relates to a method for producing a laminate and a touch panel sensor.

### 2. Description of the Related Art

In electronic components such as a touch panel sensor and a display device, a cured layer such as an interlayer insulating film is provided to maintain insulating properties between wiring lines arranged in a layered manner. A photosensitive composition is used for forming such a cured layer.

For example, in WO2018/186428A, a method in which a photosensitive composition layer is formed on a substrate having a conductive portion, and the photosensitive composition layer is exposed through a photo mask having a predetermined pattern and developed with a developer to dissolve and remove unnecessary portions, thereby forming a cured layer and producing a laminate. WO2018/186428A discloses that the conductive portions are connected to each other through an opening portion provided in the cured layer.

### SUMMARY OF THE INVENTION

In recent years, with miniaturization and higher functionality of electronic components, there is a demand for further improvement in connection reliability between conductive portions.

In a case where a conductive portion (so-called bridge wire) for conducting between transparent conductive portions exposed from a plurality of opening portions is formed and connection reliability thereof is evaluated according to the method disclosed in WO2018/186428A, the present inventors have found that the connection reliability does not meet the level demanded these days, and further improvement is necessary.

FIG. 2 is a schematic cross-sectional view showing an example of a layer structure of a transparent conductive film, which is one of usage aspects of a laminate obtained by a method in the related art such as WO2018/186428A. As shown in FIG. 2, in a transparent conductive film 30 using the laminate obtained by the method in the related art, a first transparent conductive portion 14, a patterned cured layer 16A, a second transparent conductive portion 18, and an optionally provided transparent resin layer 20 as a protective layer are laminated in this order on a surface of a base material 12. A non-formed region of the patterned cured layer 16A functions as a contact hole 22 of the transparent conductive film 30.

In a general pattern exposure, as shown in FIG. 2, a taper angle of the contact hole 22 is steep, so that in a case of forming the second transparent conductive portion 18 after forming the patterned cured layer 16A, in a corner portion of a top portion and a corner portion of a bottom portion in the contact hole 22, as shown in FIG. 2, there is a concern that a sputter link film may be poorly formed in a case where the second transparent conductive portion 18 is formed, or disconnection may occur due to stress concentration at the corner portions.

In addition, in a case where the taper angle of the contact hole 22 is steep, reflection of light on a side surface of the contact hole and reflection of light due to thickness unevenness at the corner portions are increased, and the contact hole is easily visible in the transparent conductive film. Therefore, in a case of laminating the transparent resin layer 20 as a protective layer, problems such as air bubbles being likely to be involved may occur.

Accordingly, a method of making an angle of the side surface of the patterned cured layer gentler has been considered. However, in a known exposure device in the related art, energy application efficiency in exposure, formation of high-definition pattern, and the like are important, and incidence ray at an angle close to vertical, for example, a collimation angle is approximately 1° to 5°. Therefore, it is difficult to expose at a desired incidence angle and cure the side surface of the photosensitive composition layer at the desired angle.

An object to be solved by one embodiment of the present disclosure is to provide a method for producing a laminate applicable to a touch panel sensor, in which occurrence of disconnection is suppressed in a case of forming a second transparent conductive portion after forming a contact hole.

An object to be solved by another embodiment of the present disclosure is to provide a touch panel sensor in which occurrence of a failure due to disconnection of a second transparent conductive portion is suppressed.

The methods for achieving the above-described objects include the following aspects.

<1> A method for producing a laminate, comprising:

a step 1 of preparing a laminate precursor having a base material, a first transparent conductive portion, and a photosensitive composition layer in this order;

a step 2 of pattern-exposing the photosensitive composition layer with scattered light from a side of the photosensitive composition layer opposite to a side on which the base material is provided; and

a step 3 of developing the pattern-exposed photosensitive composition layer to form a patterned cured layer.

<2> The method for producing a laminate according to <1>, in which the step 1 is a step of forming the photosensitive composition layer on a side of the first transparent conductive portion in a conductive substrate which has the base material and the first transparent conductive portion disposed on the base material, and

the step 2 is a step of performing a pattern exposure by irradiating through an exposure mask, the photosensitive composition layer with scattered light from an exposure light source disposed on the side of the photosensitive composition layer opposite to the side on which the base material is provided.

<3> The method for producing a laminate according to <1> or <2>,

in which the laminate comprises the base material, the first transparent conductive portion, and the patterned cured layer in this order, and

in which a taper angle of a wall surface of a portion having the patterned cured layer with respect to a surface direction of the base material is 35° or less.

<4> The method for producing a laminate according to any one of <1> to <3>,

in which, in the step 2, a scattering layer having a diffuse transmittance of 5% or more and an exposure light source are arranged on the side of the photosensitive composition layer opposite to the side on which the base material is provided, and

the scattered light is irradiated from the exposure light source through the scattering layer.

<5> The method for producing a laminate according to <4>,

in which a scattering angle of the scattering layer is 20° or more.

<6> The method for producing a laminate according to any one of <1> to <5>,

in which, in the step 2, on the side of the photosensitive composition layer opposite to the side on which the base material is provided, an exposure mask, a scattering layer having a diffuse transmittance of 5% or more, and an exposure light source are provided in this order from the photosensitive composition layer side.

<7> The method for producing a laminate according to any one of <1> to <5>,

in which, in the step 2, on the side of the photosensitive composition layer opposite to the side on which the base material is provided, a scattering layer having a diffuse transmittance of 5% or more, an exposure mask, and an exposure light source are provided in this order from the photosensitive composition layer side.

<8> The method for producing a laminate according to any one of <4> to <7>,

in which the scattering layer contains a matrix material and particles present in the matrix material, and

a difference in refractive index between the matrix material and the particles is 0.05 or more.

<9> The method for producing a laminate according to any one of <4> to <8>,

in which the scattering layer contains a matrix material and particles present in the matrix material, and

an average primary particle diameter of the particles is 0.3 μm or more.

<10> The method for producing a laminate according to any one of <4> to <7>,

in which the scattering layer has irregularities on at least one surface.

<11> The method for producing a laminate according to <10>,

in which the irregularities have a plurality of convex portions, and

a distance between top portions of convex portions adjacent to each other is 10 μm to 50 μm.

<12> The method for producing a laminate according to any one of <4> to <11>,

in which the scattering layer and the exposure mask are arranged at a position where the scattering layer and the exposure mask do not come into contact with each other.

<13> The method for producing a laminate according to any one of <4> to <11>,

in which the scattering layer and the exposure mask are arranged in contact with each other.

<14> The method for producing a laminate according to any one of <1> to <5>,

in which an exposure mask is a scattering exposure mask having a diffuse transmittance of 5% or more.

<15> The method for producing a laminate according to any one of <1> to <14>,

in which the step 1 includes forming the photosensitive composition layer using a transfer material which has a temporary support and at least one photosensitive composition layer disposed on the temporary support.

<16> The method for producing a laminate according to <15>,

in which the temporary support is a temporary support having a diffuse transmittance of 5% or more.

<17> The method for producing a laminate according to <15> or <16>,

in which the pattern exposure in the step 2 is a contact exposure in which an exposure mask is brought into contact with the temporary support for exposure.

<18> The method for producing a laminate according to <15>,

in which the transfer material further has a scattering layer having a diffuse transmittance of 5% or more between the temporary support and the photosensitive composition layer, and

in the transfer, the photosensitive composition layer and the scattering layer are transferred.

<19> The method for producing a laminate according to any one of <1> to <18>, further comprising, after the step 3:

a step 4 of forming a second transparent conductive portion on the patterned cured layer.

<20> A touch panel sensor comprising, in the following order:

a base material;

a first transparent conductive portion;

a cured layer having a contact hole; and

a second transparent conductive portion,

in which a taper angle of the contact hole in the cured layer with respect to a surface direction of the base material in a cross section parallel to a normal direction of the base material is 50° or less.

<21> The touch panel sensor according to <15>,

in which the taper angle is 35° or less.

According to one embodiment of the present disclosure, it is possible to provide a method for producing a laminate applicable to a touch panel sensor, in which occurrence of disconnection is suppressed in a case of forming a second transparent conductive portion after forming a contact hole.

According to another embodiment of the present disclosure, it is possible to provide a touch panel sensor in which occurrence of a failure due to disconnection of a second transparent conductive portion is suppressed.

### BRIEF DESCRIPTION OF THE DRAWINGS

FIG. 1 is a schematic cross-sectional view showing an example of a layer configuration of a transparent conductive film which is one of application aspects of a laminate obtained by a method for producing a laminate according to the present disclosure.

FIG. 2 is a schematic cross-sectional view showing an example of a layer configuration of a transparent conductive film which is one of application aspects of a laminate obtained by the producing method in the related art.

FIG. 3 is a schematic cross-sectional view showing a first aspect of a disposing position of a scattering layer in light irradiation of a step 2.

FIG. 4 is a schematic cross-sectional view showing a second aspect of a disposing position of a scattering layer in light irradiation of the step 2.

FIG. 5 is a schematic cross-sectional view showing an example that a scattering exposure mask, which is a third aspect of a disposing position of a scattering layer, is used in light irradiation of the step 2.

FIG. 6 is a schematic cross-sectional view showing a fourth aspect of a disposing position of a scattering layer in light irradiation of the step 2.

FIG. 7 is a schematic cross-sectional view showing an example that a light-scattering temporary support as a transfer material, which is a fifth aspect of a disposing position of a scattering layer, is used in light irradiation of the step 2.

FIG. 8 is a schematic cross-sectional view showing a sixth aspect of a disposing position of a scattering layer in light irradiation of the step 2.

FIG. 9 is a schematic view showing a method for measuring a taper angle of a contact hole with respect to a surface direction of a base material.

### DESCRIPTION OF THE PREFERRED EMBODIMENTS

Hereinafter, a method for producing a laminate according to an embodiment of the present disclosure will be described.

However, the present disclosure is not limited to embodiments described below, and can be implemented with appropriate modification within the scope of the object of the present disclosure.

In the present disclosure, the numerical ranges shown using “to” means ranges including the numerical values described before and after “to” as the minimum value and the maximum value.

Regarding numerical ranges that are described stepwise in the present disclosure, an upper limit value or a lower limit value described in a numerical range may be replaced with an upper limit value or a lower limit value of another stepwise numerical range. In addition, in the numerical ranges described in the present disclosure, an upper limit value and a lower limit value disclosed in a certain range of numerical values may be replaced with values shown in Examples.

In addition, in the present disclosure, a combination of two or more preferred aspects is a more preferred aspect.

In the present disclosure, in a case where plural kinds of substances corresponding to each component are present, the content of each component means a content of all of the plural kinds of substances, unless otherwise specified.

In the present disclosure, “transparent” means that an average transmittance of visible light having a wavelength of 400 nm to 700 nm is 80% or more, preferably 90% or more. That is, for example, a “transparent conductive portion” in the present disclosure indicates a conductive portion in which an average transmittance of visible light having a wavelength of 400 nm to 700 nm is 80% or more.

Here, the average transmittance of visible light is a value measured using a spectrophotometer. Examples of the spectrophotometer include a spectrophotometer U-3310 manufactured by Hitachi, Ltd.

In the present disclosure, unless otherwise specified, a content ratio of each constitutional unit of a polymer is a molar ratio.

In addition, a weight-average molecular weight (Mw) and a number-average molecular weight (Mn) in the present disclosure are molecular weights in terms of polystyrene used as a standard substance, which are detected by using tetrahydrofuran (THF), a differential refractometer, and a gel permeation chromatography (GPC) analyzer using TSKgel GMHxL, TSKgel G4000HxL, and TSKgel G2000HxL (all product names manufactured by Tosoh Corporation) as columns, unless otherwise specified.

In the present disclosure, unless otherwise specified, a molecular weight of a compound having a molecular weight distribution is the weight-average molecular weight.

In the present disclosure, as a refractive index, unless otherwise specified, a value measured with an ellipsometer at a wavelength of 550 nm is adopted.

In the present disclosure, “(meth)acryl” means at least one of acryl or methacryl, and “(meth)acrylate” means at least one of acrylate or methacrylate.

Unless otherwise specified, a notation “substituent” is used in the sense of including unsubstituted ones and those further having a substituent. For example, an expression “alkyl group” is intended to include both unsubstituted alkyl groups and alkyl groups further having a substituent. The same applies to other substituents.

In the present disclosure, a term “step” not only includes an independent step, but also includes a step, in a case where the step may not be distinguished from the other step, as long as the expected object of the step is achieved.

In the present disclosure, constituent elements indicated by the same reference numeral in the drawings mean the same constituent element.

<Method for Producing Laminate>

A method for producing a laminate according to the embodiment of the present disclosure is a method for producing a laminate including a step 1 of preparing a laminate precursor having a base material, a first transparent conductive portion, and a photosensitive composition layer in this order, a step 2 of pattern-exposing the photosensitive composition layer with scattered light from a side of the photosensitive composition layer opposite to a side on which the base material is provided, and a step 3 of developing the pattern-exposed photosensitive composition layer to form a patterned cured layer.

In addition, in the present disclosure, the product obtained in the above-described step 1, in which at least the base material, the first transparent conductive portion, and the photosensitive composition layer are laminated, is also referred to as a “laminate precursor”, and the product obtained in the above-described step 2, in which at least the base material, the first transparent conductive portion, and the pattern-exposed photosensitive composition layer are laminated, is also referred to as an “exposed laminate precursor”.

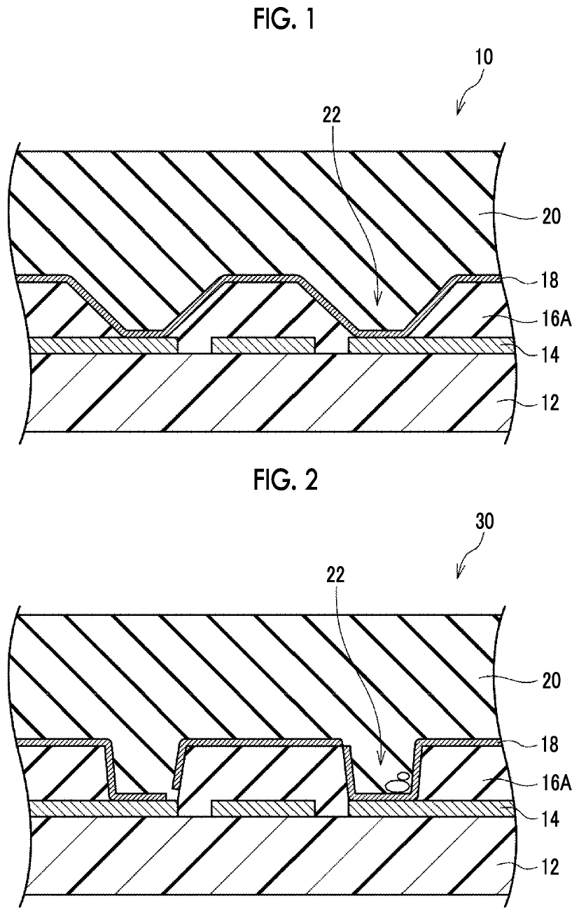

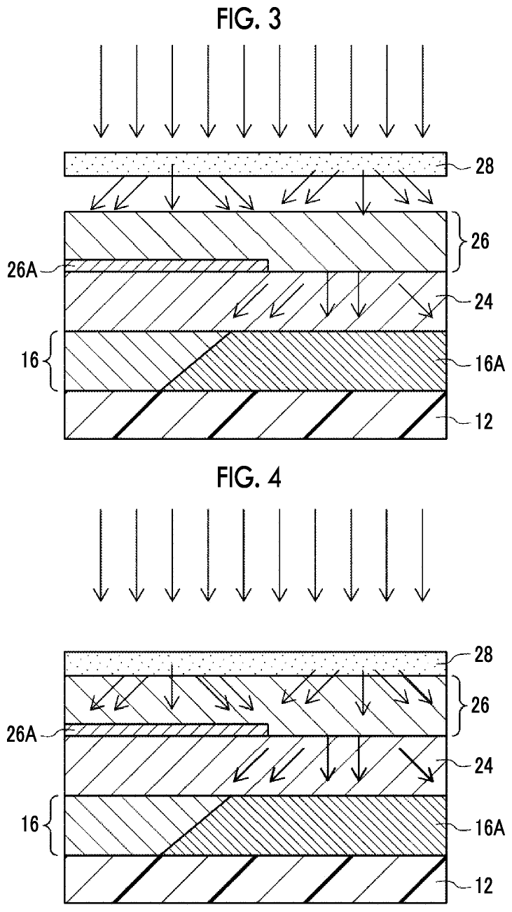

First, a layer configuration in an example of a transparent conductive film which is one of usage aspects of the laminate obtained by the method for producing a laminate according to the embodiment of the present disclosure will be described with reference to FIG. 1.

Hereinafter, the “method for producing a laminate according to the embodiment of the present disclosure” may be simply referred to as a “producing method according to the embodiment of the present disclosure”.

FIG. 1 is a schematic cross-sectional view showing a layer structure of a transparent conductive film to which a laminate obtained by the producing method according to the embodiment of the present disclosure is applied.

A transparent conductive film 10 shown in FIG. 1 has, on a surface of a base material 12, a laminate which has a first transparent conductive portion 14 and a patterned cured layer 16A, a second transparent conductive portion 18 disposed on a surface of the patterned cured layer 16A, and an optional transparent resin layer 20 as a protective layer in this order. A non-formed region of the patterned cured layer 16A functions as a contact hole 22.

In the present disclosure, the patterned cured layer 16A of the laminate is obtained by irradiating a photosensitive composition layer with scattered light in a patterned manner through an exposure mask and developing the photosensitive composition layer to remove a non-cured region of the photosensitive composition layer. In the laminate obtained by the producing method according to the embodiment of the present disclosure, as shown in FIG. 1, since a taper angle of the contact hole 22 in the cured layer 16A with respect to a surface direction of the base material 12 in a cross section parallel to a normal direction of the base material 12 is gentle, and an angle of a wall surface of the contact hole 22 in a case of being viewed from a side surface is not steep, occurrence of disconnection is suppressed in a case of forming the second transparent conductive portion after forming the contact hole. Further, the above-described configuration has advantages such as that it is easier to suppress entrainment of air bubbles in a case of laminating the transparent resin layer 20 as a protective layer, and that visibility due to reflection at a bottom surface of the contact hole 22 in a case of forming the second transparent conductive portion after forming the contact hole 22 is improved.

Hereinafter, the method for producing a laminate according to the embodiment of the present disclosure will be described in the order of steps.

[Step 1]

In the step 1, a laminate precursor having a base material, a first transparent conductive portion, and a photosensitive composition layer in this order is prepared.

A method for preparing the above-described laminate precursor is not particularly limited, and a known method can be used.

Specific preferred examples of the step 1 include a step of forming the photosensitive composition layer on a first transparent conductive portion side of a conductive substrate which has the base material and the first transparent conductive portion disposed on the base material.

It is preferable that the first transparent conductive portion disposed on the substrate is disposed in a predetermined patterned manner for forming a wiring line on the base material. A plurality of the first transparent conductive portions may be disposed on the surface of the base material depending on the purpose. In addition, the plurality of the first transparent conductive portions may communicate with each other.

Details of the base material, the first transparent conductive portion, each component of the photosensitive composition layer, and physical properties will be collectively described later.

In the step 1, the method for forming the photosensitive composition layer on the first transparent conductive portion side of the base material is not particularly limited, and a known method can be applied.

Examples of the method for forming the photosensitive composition layer include a transfer method in which, using a transfer material having a temporary support and at least one photosensitive composition layer disposed on the temporary support, the photosensitive composition layer of the transfer material is transferred onto the first transparent conductive portion side of the base material (preferably, on the conductive substrate) and a coating method in which the photosensitive composition layer is formed by applying a photosensitive composition to a surface of the first transparent conductive portion side of the base material.

From the viewpoint of efficiently forming a photosensitive composition layer which is uniform and has good planarity, the transfer method is preferably applied to form the photosensitive composition layer. The transfer material having at least on photosensitive composition layer on the temporary support, which is used in the transfer method, is also referred to as a dry film resist.

It is preferable that the step 1 includes a step of transferring, onto the conductive substrate, the photosensitive composition layer of the transfer material having the temporary support and at least one layer of the photosensitive composition layers disposed on the temporary support.

Hereinafter, the transfer method will be described in detail.

The temporary support is preferably a film and more preferably a resin film. As the temporary support, a film which has flexibility and does not show significant deformation, contraction, or stretching under pressure or under pressure and heating can be used.

Examples of such a film include a polyethylene terephthalate film (for example, a biaxially stretching polyethylene terephthalate film), a cellulose triacetate film, a polystyrene film, a polyimide film, and a polycarbonate film.

Among these, as the temporary support, a biaxially stretching polyethylene terephthalate film is particularly preferable.

It is preferable that the film used as the temporary support does not have deformation such as wrinkles or scratches.

As described in detail in the description of the step 2, a scattering temporary support may be used as the temporary support.

From the viewpoint that pattern exposure through the temporary support can be performed, it is preferable that the temporary support has high transparency, and the transmittance of light having a wavelength of 365 nm is preferably 60% or more and more preferably 70% or more.

From the viewpoint of pattern forming properties during the pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of the pattern forming properties during the pattern exposure through the temporary support and the transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

A thickness of the temporary support is not particularly limited, but from the viewpoint of easiness of handling and general-purpose properties, is preferably 5 μm to 200 μm, more preferably 10 μm to 150 μm, and still more preferably 10 μm to 50 μm.

From the viewpoint of imparting handleability, a layer (that is, lubricant layer) containing fine particles may be provided on a surface of the temporary support. The lubricant layer may be provided on one surface of the temporary support or on both surfaces thereof. A diameter of the particles contained in the lubricant layer is preferably 0.05 μm to 0.8 μm. In addition, a film thickness of the lubricant layer is preferably 0.05 μm to 1.0 μm.

Examples of the temporary support include a biaxially stretching polyethylene terephthalate film having a film thickness of 16 μm, a biaxially stretching polyethylene terephthalate film having a film thickness of 12 μm, and a biaxially stretching polyethylene terephthalate film having a film thickness of 9 μm.

For example, preferred aspects of the temporary support are described in paragraphs [0017] and [0018] of JP2014-085643A, paragraphs [0019] to [0026] of JP2016-027363A, paragraphs [0041] to [0057] of WO2012/081680A1, and paragraphs [0029] to [0040] of WO2018/179370A1, the contents of which are incorporated herein by reference.

In addition, examples of a commercially available product of the temporary support include LUMIRROR 16KS40 and LUMIRROR 16FB40 (all manufactured by Toray Industries, Inc.), and COSMOSHINE A4100, COSMOSHINE A4300, and COSMOSHINE A8300 (all manufactured by TOYOBO Co., Ltd.).

Examples of a method for forming the photosensitive composition layer on the temporary support include a method in which the photosensitive composition is applied to the temporary support and dried as necessary.

The photosensitive composition preferably includes a solvent.

As the solvent, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. As the solvent, a mixed solvent of methyl ethyl ketone and propylene glycol monomethyl ether acetate or a mixed solvent of diethylene glycol ethyl methyl ether and propylene glycol monomethyl ether acetate is preferable.

As the solvent, solvents described in paragraphs [0054] and [0055] of US2005/282073A can also be used, and the contents of this specification are incorporated in the present disclosure by reference.

In addition, as the solvent, an organic solvent having a boiling point of 180° C. to 250° C. (that is, high-boiling-point solvent) can also be used as necessary.

The photosensitive composition may include only one kind of solvent, or may include two or more kinds of solvents.

In a case where the photosensitive composition includes the solvent, the total solid content of the photosensitive composition is preferably 5% by mass to 80% by mass, more preferably 5% by mass to 40% by mass, and still more preferably 5% by mass to 30% by mass to the total mass of the photosensitive composition.

In a case where the photosensitive composition includes the solvent, for example, from the viewpoint of coatability, a viscosity of the photosensitive composition at 25° C. is preferably 1 mPa s to 50 mPa s, more preferably 2 mPa s to 40 mPa s, and still more preferably 3 mPa s to 30 mPa s. The viscosity is measured using a viscometer. As the viscometer, for example, a viscometer (product name: VISCOMETER TV-22) manufactured by Toki Sangyo Co., Ltd. can be suitably used. However, the viscometer is not limited to the above-described viscometer.

In a case where the photosensitive composition includes the solvent, from the viewpoint of coatability, a surface tension of the photosensitive composition at 25° C. is preferably 5 mN/m to 100 mN/m, more preferably 10 mN/m to 80 mN/m, and still more preferably 15 mN/m to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

Examples of the method for applying the photosensitive composition include a printing method, a spray coating method, a roll coating method, a bar coating method, a curtain coating method, a spin coating method, and a die coating method (that is, a slit coating method). Among the above, a die coating method is preferable as the coating method.

Examples of a drying method include natural drying, heating drying, and drying under reduced pressure. The above-described methods can be adopted alone or in combination of two or more thereof.

In the present disclosure, “drying” is not limited to removing all solvents included in the composition, but includes removing at least a part of solvents included in the composition to reduce a content of the solvents in the composition.

In order to protect the photosensitive composition layer, a protective film is preferably provided on the surface of the transfer film opposite to the temporary support. In a case where a refractive index-adjusting layer is further disposed on the photosensitive composition layer, the protective film is disposed at a position that protects the refractive index-adjusting layer.

The protective film is preferably a resin film, and a resin film having heat resistance and solvent resistance can be used. Examples thereof include polyolefin films such as a polypropylene (PP) film and a polyethylene (PE) film. In addition, a resin film composed of the same material as the above-described temporary support may be used as the protective film.

A thickness of the protective film is preferably 1 μm to 100 μm, more preferably 5 μm to 50 μm, still more preferably 5 μm to 40 μm, and particularly preferably 15 μm to 30 μm. In a case where the thickness of the protective film is within the above-described range, it is preferable from the viewpoint of excellent mechanical strength, good handleability, and relatively inexpensive.

In order to make it easier to peel off the protective film from the photosensitive composition layer or the refractive index-adjusting layer, it is preferable that an adhesive force between the protective film and the photosensitive composition layer or the refractive index-adjusting layer is smaller than an adhesive force between the temporary support and the photosensitive composition layer.

The number of fisheyes with a diameter of 80 μm or more in the protective film is preferably 5 pieces/m² or less. The “fisheye” means that, in a case where a material is hot-melted, kneaded, extruded, biaxially stretched, cast, or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by irregularities due to the particles included in the protective film being transferred to the photosensitive composition layer or the refractive index-adjusting layer.

From the viewpoint of imparting a take-up property, an arithmetic average roughness Ra of a surface of the protective film on a side opposite to the surface in contact with the photosensitive composition layer or the refractive index-adjusting layer is preferably 0.01 μm or more, more preferably 0.02 μm or more, and still more preferably 0.03 μm or more. On the other hand, the surface roughness Ra is preferably less than 0.50 μm, more preferably 0.40 μm or less, and still more preferably 0.30 μm or less.

From the viewpoint of suppressing defects during transfer, a surface roughness Ra of a surface of the protective film in contact with the photosensitive composition layer or the refractive index-adjusting layer is preferably 0.01 μm or more, more preferably 0.02 μm or more, and still more preferably 0.03 μm or more. On the other hand, the surface roughness Ra is preferably less than 0.50 μm, more preferably 0.40 μm or less, and still more preferably 0.30 μm or less.

In a case where the transfer material having the temporary support and at least one layer of the photosensitive composition layers disposed on the temporary support (that is, the dry film resist) has the protective film, the photosensitive composition layer can be formed on the base material by peeling off the protective film from the transfer material (dry film resist) having the protective film and attaching the transfer material to the base material (preferably on the first transparent conductive portion of the conductive substrate) such that the photosensitive composition layer side of the transfer material from which the protective film has been peeled off and the base material face each other.

A temperature at which the transfer material is attached to the base material is not particularly limited, but is preferably 80° C. to 150° C., more preferably 90° C. to 150° C., and still more preferably 100° C. to 150° C. In a case of using a laminator including a rubber roller, the laminating temperature indicates a temperature of the rubber roller.

A linear pressure in a case of attaching is preferably 0.5 N/cm to 20 N/cm, more preferably 1 N/cm to 10 N/cm, and still more preferably 1 N/cm to 5 N/cm.

The temporary support may be peeled off after the transfer material is attached to the conductive substrate, or the transfer material may be subjected to the step 2 described later without peeling off the temporary support.

[Step 2]

The step 2 is a step of pattern-exposing the above-described photosensitive composition layer with scattered light from a side of the above-described photosensitive composition layer opposite to a side on which the above-described base material is provided.

Specific examples of the step 2 include a step of performing a pattern exposure by irradiating through an exposure mask, the photosensitive composition layer with scattered light from an exposure light source disposed on the side of the above-described photosensitive composition layer opposite to the side on which the base material is provided.

As the irradiation with the scattered light, it is preferable that a scattering layer having a diffuse transmittance of 5% or more and an exposure light source are arranged on the side of the photosensitive composition layer opposite to the side on which the base material is provided, and the scattered light is irradiated from the exposure light source through the scattering layer.

In the present disclosure, the “pattern exposure” refers to exposure in a form of performing the exposure in a patterned manner, that is, exposure in a form in which an exposed portion and a non-exposed portion exist in the photosensitive composition layer.

(Exposure Light Source)

A known light source can be used as the exposure light source in the present disclosure. The exposure light source used in the above-described exposure can be appropriately selected and used as long as in can irradiate light in a wavelength range in which an exposed portion of a photosensitive transfer material can chemically react (for example, 365 nm, 405 nm, or the like). Specific examples thereof include an ultra-high pressure mercury lamp, a high pressure mercury lamp, and a metal halide lamp.

An exposure amount is preferably approximately 5 mJ/cm² to 200 mJ/cm², and more preferably approximately 10 mJ/cm² to 100 mJ/cm².

The pattern exposure may be performed after the temporary support is peeled off from the photosensitive composition layer, or the photosensitive composition layer before peeling off the temporary support may be exposed through the temporary support and then the temporary support may be peeled off. In addition, the pattern exposure may be a contact exposure in which the exposure mask is brought into contact with the temporary support for exposure.

In order to prevent mask contamination due to contact between the photosensitive composition layer and the mask and to avoid an influence of foreign substance adhering to the mask on the exposure, it is preferable to perform the exposure without peeling off the temporary support.

(Scattering Layer)

In the step 2, it is preferable that the irradiation with the scattered light is performed through a scattering layer having a diffuse transmittance of 5% or more, which is disposed between the exposure light source and the photosensitive composition layer.

Hereinafter, the “scattering layer having a diffuse transmittance of 5% or more” may be simply referred to as a “scattering layer”.

The scattering layer may be provided independently, or other layers of the laminate, for example, a base material of the exposure mask, the temporary support in the dry film resist, or the like may be provided with the function of the scattering layer by using a material having scattering properties.

An indicator of light diffuse transmittance is used for the measurement of the diffuse transmittance. The light diffuse transmittance refers to a transmittance of diffused light, which is obtained by shining light on the scattering layer and removing a parallel component from the total transmittance of light including all parallel components and diffuse components in light transmitted through the scattering layer.

The light diffuse transmittance can be obtained in accordance with JIS K 7136 “Plastic—Method for obtaining haze of transparent material (2000)”.

That is, the haze indicates a value represented by the following expression. Therefore, by using a haze meter, the diffuse transmittance of the scattering layer which is a subject can be obtained.

Cloudy value (haze) %=[Diffuse transmittance (Td)/Total light transmittance (Tt)]×100

A value using a haze meter NDH7000II of NIPPON DENSHOKU INDUSTRIES Co., Ltd. as a measuring device in the present disclosure is adopted.

The diffuse transmittance of the scattering layer is preferably 5% or more, more preferably 50% or more, still more preferably 70% or more, and particularly preferably 90% or more. The upper limit of the diffuse transmittance is not particularly limited, but may be, for example, 100%.

A scattering angle of the scattering layer is preferably 15° or more, more preferably 20° or more, still more preferably 20° or more and 60° or less, and particularly preferably 20° or more and 40° or less. Here, the scattering angle means a width (total of the positive side and the negative side) up to an angle at which, in a case where an intensity of light transmitted through the scattering layer in a vertical direction is 0°, the intensity thereof is half. The scattering angle may be expressed by the term “full angle at half maximum”.

The scattering angle can be measured using a goniometer or the like.

Scattering characteristics of light are generally symmetrical between the positive side angle and the negative side angle, but the definition of the scattering angle is not changed even in a case where the positive side angle and the negative side angle are asymmetrical.

In a case where values of the scattering angle differ depending on the orientation of the measurement surface, the maximum value in the values is defined as the scattering angle of the scattering layer.

The scattering layer is not particularly limited as long as the above-described diffuse transmittance can be achieved. Among these, from the viewpoint of ease of adjustment of the diffuse transmittance and availability, the scattering layer is preferably a scattering layer which contains a matrix material and particles present in the matrix material (hereinafter, also referred to as a scattering layer containing a matrix material and particles) or a scattering layer which has irregularities on at least one surface.

—Scattering Layer Containing Matrix Material and Particles—Examples of one aspect of the scattering layer used in the producing method according to the embodiment of the present disclosure include a layer containing a matrix material and particles which are present in the matrix material to impart light-scattering properties to the scattering layer (hereinafter, also referred to as specific particles).

The scattering layer containing the specific particles is preferably a layer in which the specific particles are dispersed and contained in a transparent matrix material.

Examples of the matrix material include glass, quartz, and a resin material.

In a case where glass or quartz is used as the matrix material, it is sufficient that the specific particles are kneaded into the glass or quartz and uniformly dispersed to form the scattering layer.

In a case where the resin material is used as the matrix material, a resin capable of forming an ultraviolet-transmissive resin layer is preferable, and examples thereof include an acrylic resin, a polycarbonate resin, a polyester resin, a polyethylene resin, a polypropylene resin, an epoxy resin, a urethane resin, and a silicone resin.

In a case where the resin material is used as the matrix material, the scattering layer can be formed by a known method. For example, a plate-like scattering layer can be obtained by melt-kneading resin pellets of the matrix material and the specific particles and then performing an injection mold. In addition, the scattering layer may be formed by curing a resin composition including a precursor monomer of the resin and the specific particles, or may be formed by curing a resin composition in which the specific particles are kneaded into a mixture including the resin material and a solvent as an optional component. The method for forming the scattering layer is not limited to the above.

In order for the specific particles to impart sufficient light-scattering properties to the scattering layer, a difference in refractive index between the matrix material and the specific particles is preferably 0.05 or more. The difference in refractive index is more preferably in a range of 0.05 to 1.0, and still more preferably in a range of 0.05 to 0.6.

In a case where the difference in refractive index between the matrix material and the specific particles is within the above-described range, it is possible to increase intensity of scattered light, and suppress decrease in application of energy due to excessive reflection of incidence ray, which is a concern in a case where the intensity of scattered light is too large. Therefore, a sufficient amount of energy to cure the photosensitive composition layer can be applied.

In order for the specific particles to impart sufficient light-scattering properties to the scattering layer, a size of the specific particles is preferably such that an average primary particle diameter is 0.3 μm or more. The average primary particle diameter of the specific particles is preferably in a range of 0.3 μm to 2.0 and more preferably in a range of 0.5 μm to 1.5 In a case where the average primary particle diameter is within the above-described range, Mie scattering of ultraviolet rays occurs and intensity of forward-scattered light increases. Therefore, a sufficient amount of energy to cure the photosensitive composition layer is easily applied.

The average primary particle diameter of the specific particles is calculated by measuring particle diameters of 200 random specific particles in a viewing angle using an electron microscope, and arithmetically averaging the measurement values.

In a case where the shape of the particle is not a spherical shape, the longest side is set as the particle diameter.

Examples of the specific particles include inorganic particles such as zirconium oxide particles (ZrO₂ particles), niobium oxide particles (Nb₂O₅ particles), titanium oxide particles (TiO₂ particles), aluminum oxide particles (Al₂O₃ particles), and silicon dioxide particles (SiO₂ particles) and organic particles such as crosslinked polymethyl methacrylate.

The scattering layer may include only one kind of the specific particles, or may include two or more kinds thereof.

A content of the specific particles is not particularly limited, and it is preferable to achieve the desired diffuse transmittance or the desired scattering angle by adjusting the type, size, content, shape, refractive index, and the like of the specific particles in the scattering layer.

The content of the specific particles may be, for example, 5% by mass to 50% by mass with respect to the total mass of the scattering layer.

—Scattering Layer Having Irregularities on At Least One Surface—

Examples of another aspect of the scattering layer include a scattering layer having irregularities on at least one surface. In a case where the scattering layer has irregularities on at least one surface, light is scattered by the irregularities, scattered light is irradiated to the photosensitive composition layer through the scattering layer.

In the irregularities of the scattering layer, a distance between top portions of convex portions adjacent to each other is preferably 10 μm to 50 μm, and more preferably 15 μm to 40 μm.

As for the irregularities, from the viewpoint of light-scattering properties, it is preferable that the convex portions adjacent to each other are in contact with each other at their bottom portions, and are densely formed without gaps or the like.

By adjusting the size and shape of the convex portion, a formation density of the convex portions per unit area, and the like, the desired diffuse transmittance or the desired scattering angle can be achieved. The shape of the convex portion is not particularly limited, and is appropriately selected from a hemispherical shape, a conical shape, a pyramidal shape, a ridged shape, and the like depending on the desired diffuse transmittance, diffusion angle, and the like.

A commercially available product may be used for the scattering layer having irregularities on at least one surface. Examples of the commercially available product include Lens shaping diffuser (registered trademark) product name (the same applies hereinafter) LSD5ACUVT10, LSD 10ACUVT10, LSD20ACUVT10, LSD30ACUVT10, LSD40ACUVT10, LSD60ACUVT10, and LSD80ACUVT10 (all of which are made of a UV transparent acrylic resin); Lens shaping diffuser (registered trademark) LSD5AC10, LSD10AC10, LSD20AC10, LSD30AC10, LSD40AC10, LSD60AC10, and LSD80AC10 (all of which are made of an acrylic resin); Lens shaping diffuser (registered trademark) LSD5PC10, LSD10PC10, LSD20PC10, LSD30PC10, LSD40PC10, LSD60PC10, LSD80PC10, LSD60×10PC10, LSD60×1PC10, LSD40×1PC10, and LSD30×5PC10 (all of which are made of a polycarbonate); and Lens shaping diffuser (registered trademark) LSD5U3PS (made of quartz glass), which are manufactured by OPTICAL SOLUTIONS.

Examples of other scattering layers include a fly-eye lens FE-10 manufactured by Nihon Tokushu Kogaku Jushi Co., Ltd.; Diffuser manufactured by FIT corporation; SDXK-1FS, SDXK-AFS, and SDXK-2FS manufactured by SUNTECHOPT; a light diffusion film MX manufactured by Fillplus, Inc.; acrylic diffusers ADF901, ADF852, ADF803, ADF754, ADF705, ADF656, ADF607, ADF558, ADF509, and ADF451 manufactured by SHIBUYA OPTICAL CO., LTD.; Nanobuckling (registered trademark) manufactured by Oji F-Tex Co., Ltd.; light diffusion films HDA060, HAA120, GBA110, DCB200, FCB200, IKA130, and EDB200 manufactured by LINTEC Corporation; Scotchal (registered trademark) light diffusion films 3635-30 and 3635-70 manufactured by 3M Japan; LIGHT-UP (registered trademark) SDW, EKW, K2S, LDS, PBU, GM7, SXE, MXE, SP6F, Optsaver (registered trademark) L-9, L-11, L-19, L-20, L-35, L-52, L-57, STC3, and STE3, and Chemical Matte (registered trademark) 75PWX, 125PW, 75PBA, 75BLB, and 75PBB, all of which are manufactured by KIMOTO; Opalus (registered trademark) PBS-689G, PBS-680G, PBS-689HF, PBS-680HG, PBS-670G, UDD-147D2, UDD-148D2, SHBS-227C1, SHBS-228C2, UDD-247D2, PBS-630L, PBS-630A, PBS-632A, BS-539, BS-530, BS-531, BS-910, BS-911, and BS-912 manufactured by KEIWA Inc.; Legenda (registered trademark) PC, CL, HC, OC, TR, MC, SQ, EL, and OE manufactured by KURARAY CO., LTD.; and D120P, D121UPZ, D121UP, D261SIIIJ1, D261IVJ1, D263SIII, 526351V, D171, D171S, and D174S manufactured by TSUJIDEN CO., LTD.

A thickness of the scattering layer is preferably 2 mm or less, more preferably 1 mm or less, and still more preferably 100 μm or less.

The thickness of the scattering layer is preferably 0.5 μm or more, and more preferably 1 μm or more.

For the thickness of the scattering layer, an arithmetic mean value of measured values at any five points, which are measured by observing a cross section of the scattering layer with a scanning electron microscope (SEM), is adopted.

The irradiation with scattered light is not limited to light irradiation through an independent scattering layer.

For example, a scattering exposure mask in which layers other than a light shielding unit in the exposure mask having light-scattering properties, a scattering temporary support in which a temporary support in a transfer material has light-scattering properties, or the like can be used. In a case where the scattering exposure mask is used, light passing through the exposure mask is scattered light. In addition, in a case where the scattering temporary support in which the temporary support has light-scattering properties is used, by performing, after transferring the photosensitive composition layer onto the base material, exposure without peeling off the scattering temporary support, light passing through the scattering temporary support is scattered light.

In the irradiation with scattered light in the step 2, the disposing position of the scattering layer is not particularly limited as long as it is between the exposure light source and the photosensitive composition layer.

For example, the exposure mask, the scattering layer having a diffuse transmittance of 5% or more, and the exposure light source may be provided in this order on the side of the above-described photosensitive composition layer opposite to the side on which the above-described base material is provided, or the scattering layer having a diffuse transmittance of 5% or more, the exposure mask, and the exposure light source may be provided in this order on the side of the above-described photosensitive composition layer opposite to the side on which the above-described base material is provided.

Examples of a disposing position of the scattering layer in a case where the scattered light is irradiated through the scattering layer will be described with reference to the drawings.

FIG. 3 is a schematic cross-sectional view showing a first aspect of the disposing position of the scattering layer in light irradiation of the step 2. The exposed laminate precursor shown in FIG. 3 has a base material 12, a photosensitive composition layer 16, a polyethylene terephthalate (PET) film as a temporary support 24, and an exposure mask 26 having a light shielding region 26A, and on an exposure light source (not shown) side (a side opposite to the side of the photosensitive composition layer 16, on which the base material 12 is provided), a scattering layer 28 is disposed at a position not in contact with the exposure mask 26.

In FIGS. 3 to 8, an optical path of irradiation light is schematically indicated by an arrow.

As shown in FIG. 3, since the scattered light passing through the scattering layer 28 is scattered at an angle with respect to the normal direction of the photosensitive composition layer 16 (that is, scattered in a direction inclined with respect to the normal direction of the photosensitive composition layer 16), a side surface of the patterned cured layer 16A, which is formed in a cured region of the photosensitive composition layer 16, has a gentle inclination with respect to a surface direction of the base material. A taper angle of the side surface of the patterned cured layer 16A with respect to the surface direction of the base material is preferably 50° or less.

FIG. 4 is a schematic cross-sectional view showing a second aspect of the disposing position of the scattering layer in light irradiation of the step 2. The exposed laminate precursor in FIG. 4 has the same layer structure as the exposed laminate precursor shown in FIG. 3. In the second aspect shown in FIG. 4, the scattering layer 28 and the exposure mask 26 are arranged in contact with each other.

The scattering layer 28 may be integrally formed on the surface of the exposure mask 26 on the light source side by coating, sticking, or the like.

Even in the second aspect shown in FIG. 4, the scattered light passing through the scattering layer 28 is incident on a region of the exposure mask 26, where does not have the light shielding region 26A, so that, as shown in FIG. 4, the patterned cured layer 16A which is formed in a cured region of the photosensitive composition layer 16 has a gentle inclination with respect to the surface direction of the base material in a case of being viewed from the side surface. A taper angle of the patterned cured layer 16A with respect to the surface direction of the base material in the cross section parallel to the normal direction of the base material is preferably 50° C. or less.

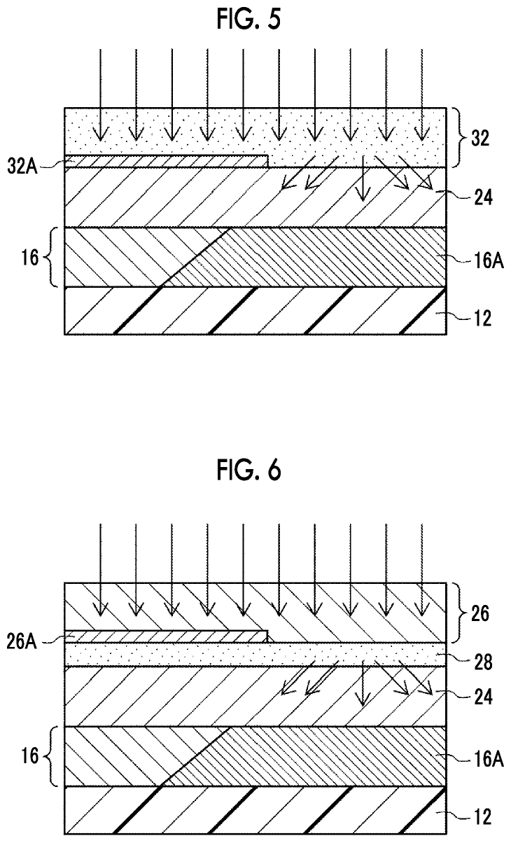

FIG. 5 is a schematic cross-sectional view showing an example that a scattering exposure mask, which is a third aspect of the disposing position of the scattering layer, is used in light irradiation of the step 2.

In the third aspect shown in FIG. 5, a scattering exposure mask 32 having a diffuse transmittance of 5% or more is used as the exposure mask. The scattering exposure mask 32 is a scattering exposure mask 32 having a light shielding region 32A in a desired region of the base material having scattering properties. The diffuse transmittance of the scattering exposure mask is as described above.

In the third aspect shown in FIG. 5, light irradiated from the exposure light source (not shown) disposed on the side opposite to the side of the photosensitive composition layer 16, on which the base material 12 is provided, passes through the scattering exposure mask 32 to be scattered light, and the scattered light is incident on the photosensitive composition layer 16 at an angle with respect to the normal direction of the base material, so that, as shown in FIG. 5, the patterned cured layer 16A which is formed in a cured region of the photosensitive composition layer 16 has a gentle inclination with respect to the surface direction of the base material in a case of being viewed from the side surface. A taper angle of the patterned cured layer 16A with respect to the surface direction of the base material in the cross section parallel to the normal direction of the base material is preferably 50° C. or less.

FIG. 6 is a schematic cross-sectional view showing a fourth aspect of the disposing position of the scattering layer in light irradiation of the step 2. The fourth aspect is an example of an aspect in which the PET film as the temporary support 24 of the transfer material, the scattering layer 28, the exposure mask 26, and the exposure light source (not shown) are provided in this order on the side opposite to the side of the photosensitive composition layer 16, on which the base material 12 is provided.

The scattering layer 28 may be integrally formed on a surface of the exposure mask 26 on the temporary support side by coating, sticking, or the like, or may be integrally formed on a surface of the PET film as the temporary support 24 on the exposure mask side by coating, sticking, or the like.

In the fourth aspect shown in FIG. 6, the exposed laminate precursor has the base material 12, the photosensitive composition layer 16, the PET film as the temporary support 24, the scattering layer 28, and the exposure mask 26 having the light shielding region 26A in this order, and light irradiated from the exposure light source (not shown) is incident on the exposure mask 26, passes through the temporary support 24 as scattered light which has passed through the scattering layer 28 from a non-formed region of the light shielding region 26A in the exposure mask 26 to be scattered light, and is incident on the photosensitive composition layer 16. Since the irradiated light is incident on the photosensitive composition layer 16 at an angle as the scattered light through the scattering layer 28 from the non-formed region of the light shielding region 26A in the exposure mask 26, as shown in FIG. 6, a side surface portion of the patterned cured layer 16A, which is formed in a cured region in the photosensitive composition layer 16, has a gentle inclination with respect to the surface direction of the base material 12. A taper angle of the patterned cured layer 16A with respect to the surface direction of the base material 12 in the cross section parallel to the normal direction of the base material 12 is preferably 50° C. or less.

FIG. 7 is a schematic cross-sectional view showing an example that a light-scattering temporary support in a transfer material, which is a fifth aspect of the disposing position of the scattering layer, is used in light irradiation of the step 2.

The fifth aspect shown in FIG. 7 indicates an example in which, in the transfer material used in a case of disposing the photosensitive composition layer 16 on the base material 12, that is, the transfer material having the photosensitive composition layer 16 on the temporary support, a scattering temporary support 34 having a diffuse transmittance of 5% or more is used as the temporary support. The diffuse transmittance of the scattering temporary support 34 is as described above.

In the fifth aspect shown in FIG. 7, since the scattering temporary support 34 is used as the temporary support, it is not necessary to separately dispose the scattering layer, and the producing method according to the embodiment of the present disclosure can be implemented with a simpler configuration.

As the scattering temporary support 34, the same one as the scattering layer described above, for example, a temporary support containing a matrix material such as a resin and a polymerizable compound as a resin precursor and the specific particles, a temporary support having irregularities on one side and having scattering properties, and the like, may be used. Details of the matrix material, the specific particles, and the irregularities are as described above.

In the fifth aspect, light incident from a non-formed region of the light shielding region 26A in the exposure mask 26 passes through the scattering temporary support 34, and is incident on the photosensitive composition layer 16 as scattered light. Even in the fifth aspect, since the irradiation light is scattered at an angle in the photosensitive composition layer 16 as the scattered light, as shown in FIG. 7, a side surface portion of the patterned cured layer 16A, which is formed in a cured region in the photosensitive composition layer 16, has a gentle inclination with respect to the surface direction of the base material 12. A taper angle of the patterned cured layer 16A with respect to the surface direction of the base material 12 in the cross section parallel to the normal direction of the base material 12 is preferably 50° C. or less.

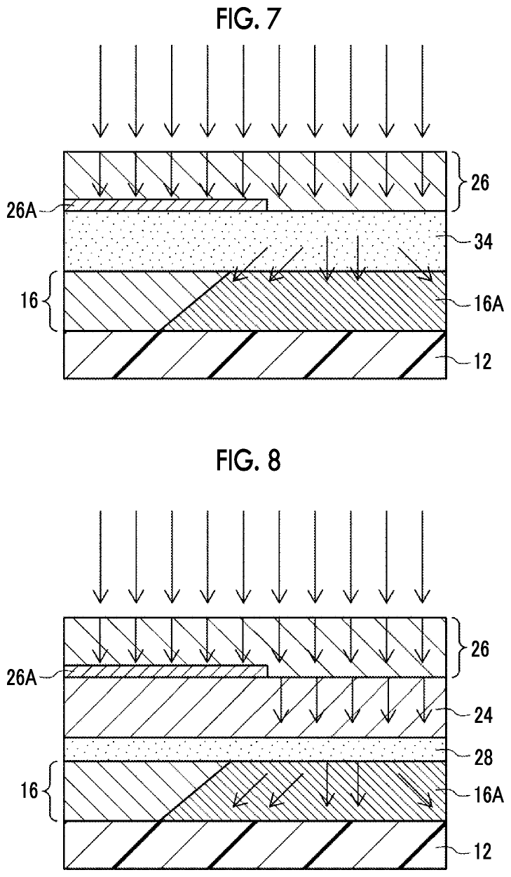

FIG. 8 is a schematic cross-sectional view showing a sixth aspect of the disposing position of the scattering layer in light irradiation of the step 2. In the sixth aspect shown in FIG. 8, the scattering layer 28 is provided between the PET film as the temporary support 24 and the photosensitive composition layer 16. In the sixth aspect, the scattering layer 28 is provided between the PET film as the temporary support 24 and the photosensitive composition layer 16.

The exposed laminate precursor according to the sixth aspect can be formed of, as a transfer material for forming the photosensitive composition layer 16 on the base material 12, a transfer material having the scattering layer 28 and the photosensitive composition layer 16 in this order on the PET film as the temporary support 24.

In a case of forming the exposed laminate precursor according to the sixth aspect, the transfer material may be formed by applying, to the temporary support 24, a scattering layer forming composition which contains a matrix material such as a resin and a polymerizable compound as a resin precursor and the specific particles to form the scattering layer, and then forming the photosensitive composition layer by a known method. Details of the matrix material and the specific particles are as described above.

In the exposed laminate precursor according to the sixth aspect, as shown in FIG. 8, light irradiated from the exposure light source (not shown) is incident, as linear light, through the exposure mask 26 from a non-formed region of the light shielding region 26A in the exposure mask 26, passes through the scattering layer 28 disposed between the temporary support 24 and the photosensitive composition layer 16, and is incident on the photosensitive composition layer 16 as scattered light. Even in the sixth aspect, since the irradiation light is scattered at an angle in the photosensitive composition layer 16 as the scattered light, as shown in FIG. 8, a side surface portion of the patterned cured layer 16A, which is formed in a cured region in the photosensitive composition layer 16, has a gentle inclination with respect to the surface direction of the base material 12. A taper angle of the patterned cured layer 16A with respect to the surface direction of the base material 12 in the cross section parallel to the normal direction of the base material 12 is preferably 50° C. or less.

In any aspect of the producing method according to the embodiment of the present disclosure, the photosensitive composition layer is irradiated with scattered light in a patterned manner from the exposure light source through the exposure mask. Therefore, since the side surface portion of the patterned cured layer, which is formed in the cured region in the photosensitive composition layer, has a gentle inclination with respect to the surface direction of the base material, and the side surface is unlikely to be steeply inclined, a laminate having various advantages as described above can be formed.

For the purpose of improving linearity of the pattern after the exposure, it is also preferable to perform a heat treatment before the step 3. By a step referred to as a so-called post exposure bake (PEB), it is possible to reduce roughness of pattern edges due to standing waves generated in the photosensitive composition layer during the exposure.

[Step 3]

The step 3 is a step of developing the pattern-exposed photosensitive composition layer to form a patterned cured layer.

By performing the step 3, the patterned cured layer is formed on the conductive substrate, and a space between the patterned cured layers is, for example, the contact hole of the transparent conductive film.

As a developer used for the development, a known developer can be adopted. Examples of the developer include developers described in JP1993-072724A (JP-H5-072724A).

As the developer, an alkaline aqueous solution is preferable. Examples of an alkaline compound which can be included in the alkaline aqueous solution include sodium hydroxide, potassium hydroxide, sodium carbonate, potassium carbonate, sodium hydrogen carbonate, potassium hydrogen carbonate, tetramethyl ammonium hydroxide, tetraethyl ammonium hydroxide, tetrapropyl ammonium hydroxide, tetrabutylammonium hydroxide, and choline (2-hydroxyethyltrimethyl ammonium hydroxide).

An pH of the alkaline aqueous solution at 25° C. is preferably 8 to 13, more preferably 9 to 12, and still more preferably 10 to 12.

A content of the alkaline compound in the alkaline aqueous solution is preferably 0.1% by mass to 5% by mass and more preferably 0.1% by mass to 3% by mass with respect to the total mass of the alkaline aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

The concentration of the organic solvent in the developer is preferably 0.1% by mass to 30% by mass.

The developer may include a surfactant.

The concentration of the surfactant in the developer is preferably 0.01% by mass to 10% by mass.

Examples of the developing method include methods such as puddle development, shower development, spin development, and dip development.

A liquid temperature of the developer in a case of the development is preferably 20° C. to 40° C.

In a case of the shower development, a part of the photosensitive composition layer is removed by spraying the developer to the photosensitive composition layer after the pattern exposure as a shower.

In addition, after the development, it is also preferable that the development residue is removed by spraying a washing agent with a shower and rubbing with a brush or the like.

The shape of a side surface portion of the patterned cured layer formed through the step 3, that is, a wall surface of a portion having the cured layer has a gentle inclination with respect to the surface direction of the base material.

A taper angle of the wall surface of the portion having the patterned cured layer with respect to the surface direction of the base material is preferably 50° or less, more preferably 40° or less, and still more preferably 30° or less.

The lower limit of the taper angle is not particularly limited, but in consideration of the function as the contact hole, may be 10° or more.

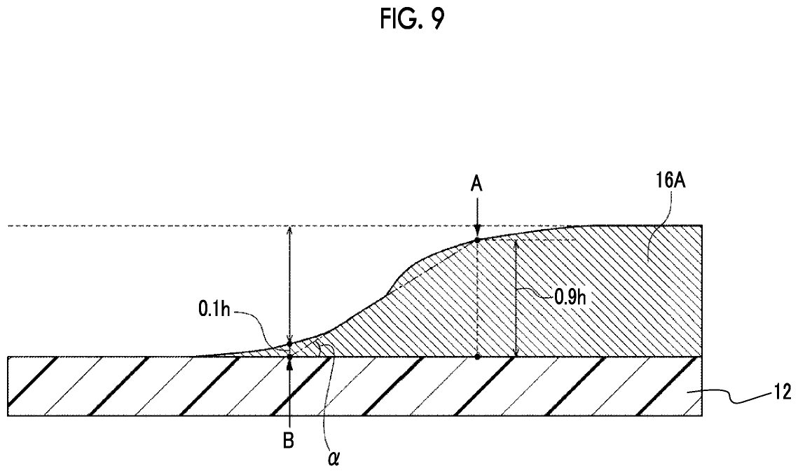

A method for measuring the taper angle of the side surface of the patterned cured layer 16A in the present disclosure will be described with reference to FIG. 9.

As shown in FIG. 9, a film thickness of a flat region which is sufficiently distant from the contact hole formed in the patterned cured layer 16A formed on the base material 12 is defined as h. Here, the film thickness of the patterned cured layer formed through the step 3 is measured in a state after performing all steps including post-baking, post-exposure, and the like, which are optionally performed after the step 3, and before performing a step 4 described later.

With respect to the film thickness h of the flat region described above, in the formed patterned cured layer 16A, a point where the thickness of the cured layer 16A is 0.9 h is defined as A. In addition, a point where the thickness of the cured layer 16A is 0.1 h is detected, and from this point, an intersection point between a bottom surface of the cured layer 16A and an imaginary line drawn perpendicular to the bottom surface of the cured layer 16A is defined as B.

In FIG. 9, an angle α formed by an imaginary line [dashed line in FIG. 9] connecting the points A and B determined above with a straight line and the bottom surface of the cured layer 16A is defined as the taper angle of the cured layer 16A.

The thickness of the patterned cured layer is measured by observing a cross section of the patterned cured layer with a scanning electron microscope (SEM). A measurement (calculation) of the taper angle based on the thickness is performed at any five points of the laminate, and an arithmetic mean of the obtained values is defined as the taper angle of the patterned cured layer.

In addition to the above-described step of performing development with the developer, the step 3 may further include a step of heat-treating the patterned cured layer formed by the development. Hereinafter, the heat treatment after development may be referred to as “post-baking”. By performing the post-baking, hardness of the cured layer is further improved.

In a case where the base material is the resin base material, a temperature of the post-baking is preferably 100° C. to 160° C. and more preferably 130° C. to 160° C.

In a case where the photosensitive composition layer used for forming the cured layer includes a (meth)acrylic resin having a carboxy group, at least a part of the (meth)acrylic resin can be changed to carboxylic acid anhydride by the post-baking. In a case of being changed to carboxylic acid anhydride, the hardness of the cured layer is improved.

In addition to the above-described step of performing development with the developer, the step 3 may further include a step of exposing the patterned cured layer obtained by the development. Hereinafter, the exposure treatment after development may be referred to as “post-exposure”. In a case where both of the post-exposing step and the post-baking step are included in the step 3, it is preferable that the post-baking is performed after the post-exposure.

With regard to the pattern exposure and the development, for example, a description described in paragraphs [0035] to [0051] of JP2006-023696A can be referred to.

The shape of an opening portion (that is, the contact hole) formed by the patterned cured layer in the step 3 is not particularly limited, and examples thereof include a circular shape, an elliptical shape, a polygonal shape, a fine linear shape, and an amorphous shape.

Among these, a circular shape or an elliptical shape is preferable, and a so-called hole pattern is preferably formed.

By performing the steps 1 to 3, a laminate having a patterned cured layer suitable for the transparent conductive film can be obtained.

The producing method according to the embodiment of the present disclosure may further include any other step in addition to the steps 1 to 3.

[Step 4]

The producing method according to the embodiment of the present disclosure can further include a step 4 of forming a second transparent conductive portion on the patterned cured layer after the step 3.

In the laminate obtained by the producing method according to the embodiment of the present disclosure, by forming the second transparent conductive portion on the patterned cured layer, a transparent conductive film having the layer configuration as shown in FIG. 1 can be obtained.

The second transparent conductive portion is preferably a transparent conductive film such as an ITO film and an IZO film, a metal film such as Al, Zn, Cu, Fe, Ni, Cr, Mo, Ag, and Au, or a film selected from the group consisting of a plurality of metal alloy films such as copper-nickel alloy. Among these, from the viewpoint of good transparency, the second transparent conductive portion is preferably made of a transparent conductive film such as an ITO film and an IZO film.

From the viewpoint of conductivity and transparency, a thickness of the second transparent conductive portion is preferably 0.01 μm to 1 μm, and more preferably 0.03 μm to 0.5 μm.

The thickness of the second transparent conductive portion is measured in the same manner as in the first transparent conductive portion.

A known method can be applied as a method for forming the second transparent conductive portion. Examples of the forming method include a method of forming a film on the patterned cured layer by a sputtering method or a coating method, and then etching a predetermined region by a known method.

Since the patterned cured layer in the laminate obtained by the producing method according to the embodiment of the present disclosure has a gentle inclination on the side surface, in a case of forming the transparent conductive portion by the sputtering method, compared to a patterned cured layer having a steep side surface, occurrence of disconnection due to the presence of corner portion is suppressed, which is preferable.

The step 4 may further has a step of, after forming the second transparent conductive portion, forming the transparent resin layer 20 as a protective layer as shown in FIG. 1. From the viewpoint of improving visibility, it is preferable that a refractive index-adjusting layer is provided on the second transparent conductive portion side of the transparent resin layer. The transparent resin layer is preferably a film obtained by curing a composition similar to the photosensitive composition used in the producing method according to the embodiment of the present disclosure.

Since the patterned protective layer obtained by the producing method according to the embodiment of the present disclosure has a gentle inclination on the side surface, there is an advantage of easily suppressing entrainment of air bubbles at the corner portion of the bottom surface in a case of laminating the transparent resin layer 20.

In a case where the laminate obtained by the producing method according to the embodiment of the present disclosure is applied to a touch panel sensor, the first transparent conductive portion and the second transparent conductive portion described above can function as a so-called sensor electrode.

It is preferable that the patterned cured layer and the transparent resin layer are achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

Hereinafter, the base material, the first transparent conductive portion, the photosensitive composition layer, and the like will be described in detail.

(Base Material)

The type of the base material which can be used in the laminate of the present disclosure is not particularly limited.

In consideration of the purpose of use of the transparent conductive film, a transparent base material is preferable.

As the base material, a glass base material or a resin base material is preferable, and a resin base material is more preferable. Therefore, as the base material, a transparent resin base material is more preferable.

Examples of the glass base material include tempered glass such as GORILLA GLASS (registered trademark) manufactured by Corning Incorporated.

As the resin base material, it is preferable to use a base material selected from the group consisting of a resin base material having no optical distortion and a resin base material having high transparency.

Examples of a preferred resin constituting the resin base material include polyethylene terephthalate (PET), polyethylene naphthalate (PEN), polycarbonate (PC), triacetyl cellulose (TAC), polyimide (PI), polybenzoxazole (PBO), and cycloolefin polymer (COP).

As a material of the transparent resin base material, for example, a material described in JP2010-086684A, JP2010-152809A, or JP2010-257492A is preferable.

(First Transparent Conductive Portion)

A material included in the first transparent conductive portion is not particularly limited as long as it is a conductive material which can impart the required conductivity.

Examples of the conductive material include indium tin oxide (ITO), indium zinc oxide (IZO), aluminum zinc oxide (AZO), and silver nanowires.

In a case where the first transparent conductive portion is formed of a metal oxide, a refractive index is preferably 1.50 to 2.20 and more preferably 1.70 to 2.00.

A known method can be applied as a method for forming the first transparent conductive portion. Examples of the forming method include a sputtering method and a coating method.

From the viewpoint of conductivity and transparency, a thickness of the first transparent conductive portion is preferably 0.01 μm to 1 μm, and more preferably 0.03 μm to 0.5 μm.

For the thickness of the first transparent conductive portion, an arithmetic mean value of measured values at any five points, which are measured by observing a cross section of the first transparent conductive portion with a scanning electron microscope (SEM), is adopted.

The disposing position of the first transparent conductive portion on the base material is not particularly limited, and the first transparent conductive portion is appropriately disposed according to purpose. It is preferable that a plurality of first transparent conductive portions are arranged on the base material. More specifically, it is preferable that a plurality of first transparent conductive portions are discretely arranged on the base material. It is preferable that the transparent conductive portions arranged discretely are electrically connected to each other a second transparent conductive portion described later.

(Photosensitive Composition Layer)

The photosensitive composition layer can be a photosensitive composition layer which is cured by being exposed to light. The photosensitive composition layer in the present disclosure may be a so-called negative tone photosensitive composition layer (curable type photosensitive composition layer).

The photosensitive composition layer may include a polymerizable compound, a polymerization initiator, and other components.

—Polymerizable Compound—It is preferable that the photosensitive composition layer includes a polymerizable compound.

The polymerizable compound is a compound having a polymerizable group. Examples of the polymerizable group include a radically polymerizable group and a cationically polymerizable group, and from the viewpoint of improving curing sensitivity, a radically polymerizable group is preferable.

The polymerizable compound preferably includes a polymerizable compound having an ethylenically unsaturated group (hereinafter, also simply referred to as an “ethylenically unsaturated compound”).

As the ethylenically unsaturated group, a (meth)acryloyl group is preferable.

The ethylenically unsaturated compound preferably includes a bi- or higher functional ethylenically unsaturated compound. Here, the “bi- or higher functional ethylenically unsaturated compound” means a compound having two or more ethylenically unsaturated groups in one molecule.

As the ethylenically unsaturated compound, a (meth)acrylate compound is preferable.

From the viewpoint of film hardness after curing, for example, the ethylenically unsaturated compound preferably includes a bifunctional ethylenically unsaturated compound (preferably a bifunctional (meth)acrylate compound) and a tri- or higher functional ethylenically unsaturated compound (preferably a tri- or higher functional (meth)acrylate compound).

Examples of the bifunctional ethylenically unsaturated compound include tricyclodecane dimethanol di(meth)acrylate, tricyclodecane diethanol di(meth)acrylate, 1,9-nonanediol di(meth)acrylate, 1,10-decanediol di(meth)acrylate, dioxane glycol di(meth)acrylate, and 1,6-hexanediol di(meth)acrylate.

Examples of a commercially available product of the bifunctional ethylenically unsaturated compound include tricyclodecane dimethanol diacrylate [product name: NK ESTER A-DCP, manufactured by Shin-Nakamura Chemical Co., Ltd.], tricyclodecane dimethanol dimethacrylate [product name: NK ESTER DCP, manufactured by Shin-Nakamura Chemical Co., Ltd.], 1,9-nonanediol diacrylate [product name: NK ESTER A-NOD-N, manufactured by Shin-Nakamura Chemical Co., Ltd.], 1,10-decanediol diacrylate [product name: NK ESTER A-DOD-N, manufactured by Shin-Nakamura Chemical Co., Ltd.], 1,6-hexanediol diacrylate [product name: NK ESTER A-HD-N, manufactured by Shin-Nakamura Chemical Co., Ltd.], and dioxane glycol diacrylate (KAYARAD R-604 manufactured by Nippon Kayaku Co., Ltd.).

Examples of the tri- or higher functional ethylenically unsaturated compound include dipentaerythritol (triketra/penta/hexa)(meth)acrylate, pentaerythritol (tri/tetra)(meth)acrylate, trimethylolpropane tri(meth)acrylate, ditrimethylolpropane tetra(meth)acrylate, isocyanuric acid (meth)acrylate, and glycerin tri(meth)acrylate.

Here, the “(tri/tetra/penta/hexa)(meth)acrylate” is a concept including tri(meth)acrylate, tetra(meth)acrylate, penta(meth)acrylate, and hexa(meth)acrylate. In addition, the “(tri/tetra)(meth)acrylate” is a concept including tri(meth)acrylate and tetra(meth)acrylate.

The tri- or higher functional ethylenically unsaturated compound is not particularly limited in the upper limit of the number of functional groups, but the number of functional groups can be, for example, 20 or less, or can be 15 or less.

Examples of a commercially available product of the tri- or higher functional ethylenically unsaturated compound include dipentaerythritol hexaacrylate [product name: KAYARAD DPHA, manufactured by Shin-Nakamura Chemical Co., Ltd.].

The ethylenically unsaturated compound more preferably includes 1,9-nonanediol di(meth)acrylate or 1,10-decanediol di(meth)acrylate, and dipentaerythritol (tri/tetra/penta/hexa)(meth)acrylate.

Examples of the ethylenically unsaturated compound also include a caprolactone-modified compound of a (meth)acrylate compound [KAYARAD (registered trademark) DPCA-20 manufactured by Nippon Kayaku Co., Ltd., A-9300-1CL manufactured by Shin-Nakamura Chemical Co., Ltd., or the like], an alkylene oxide-modified compound of a (meth)acrylate compound [KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like], and ethoxylated glycerin triacrylate [NK ESTER A-GLY-9E manufactured by Shin-Nakamura Chemical Co., Ltd., or the like].

Examples of the ethylenically unsaturated compound also include a urethane (meth)acrylate compound. As the urethane (meth)acrylate compound, a tri- or higher functional urethane (meth)acrylate compound is preferable. Examples of the tri- or higher functional urethane (meth)acrylate compound include 8UX-015A [manufactured by Taisei Fine Chemical Co., Ltd.], NK ESTER UA-32P [manufactured by Shin-Nakamura Chemical Co., Ltd.], and NK ESTER UA-1100H [manufactured by Shin-Nakamura Chemical Co., Ltd.].

From a viewpoint of improving developability, the ethylenically unsaturated compound preferably includes an ethylenically unsaturated compound having an acid group.

Examples of the acid group include a phosphoric acid group, a sulfonic acid group, and a carboxy group. Among these, as the acid group, a carboxy group is preferable.

Examples of the ethylenically unsaturated compound having an acid group include a trifunctional or tetrafunctional ethylenically unsaturated compound having an acid group [compound obtained by introducing a carboxy group to pentaerythritol tri- and tetraacrylate (PETA) skeletons (acid value: 80 mgKOH/g to 120 mgKOH/g)], and a penta- or hexafunctional ethylenically unsaturated compound having an acid group (compound obtained by introducing a carboxy group to a dipentaerythritol penta- or hexaacrylate (DPHA) skeleton [acid value: 25 mgKOH/g to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one compound selected from the group consisting of a bi- or higher functional ethylenically unsaturated compound having a carboxy group and a carboxylic acid anhydride thereof is preferable. In a case where the ethylenically unsaturated compound having an acid group is at least one compound selected from the group consisting of a bi- or higher functional ethylenically unsaturated compound having a carboxy group and a carboxylic acid anhydride thereof, the developability and the film hardness are further enhanced.

Examples of the bi- or higher functional ethylenically unsaturated compound having a carboxy group include ARONIX (registered trademark) TO-2349 [manufactured by Toagosei Co., Ltd.], ARONIX (registered trademark) M-520 [manufactured by Toagosei Co., Ltd.], and ARONIX (registered trademark) M-510 [manufactured by Toagosei Co., Ltd.].

As the ethylenically unsaturated compound having an acid group, polymerizable compounds having an acid group, which are described in paragraphs [0025] to [0030] of JP2004-239942A, can be preferably used, and the contents described in this publication are incorporated herein by reference.

A molecular weight of the ethylenically unsaturated compound is preferably 200 to 3,000, more preferably 250 to 2,600, still more preferably 280 to 2,200, and particularly preferably 300 to 2,200.

A content of the ethylenically unsaturated compound having a molecular weight of 300 or less among the ethylenically unsaturated compounds is preferably 30% by mass or less, more preferably 25% by mass or less, and still more preferably 20% by mass or less with respect to a content of all ethylenically unsaturated compounds included in the photosensitive composition layer.

The photosensitive composition layer may include only one kind of ethylenically unsaturated compound, or may include two or more kinds of ethylenically unsaturated compounds.

A content of the ethylenically unsaturated compound is preferably 1% by mass to 70% by mass, more preferably 10% by mass to 70% by mass, still more preferably 20% by mass to 60% by mass, and particularly preferably 20% by mass to 50% by mass with respect to the total mass of the photosensitive composition layer.

In a case where the photosensitive composition layer includes the bi- or higher functional ethylenically unsaturated compound, the photosensitive composition layer may further include a monofunctional ethylenically unsaturated compound.

In a case where the photosensitive composition layer includes the bi- or higher functional ethylenically unsaturated compound, it is preferable that the bi- or higher functional ethylenically unsaturated compound is a main component of ethylenically unsaturated compounds included in the photosensitive composition layer.

In a case where the photosensitive composition layer includes the bi- or higher functional ethylenically unsaturated compound, a content of the bi- or higher functional ethylenically unsaturated compound is preferably 60% by mass to 100% by mass, more preferably 80% by mass to 100% by mass, and still more preferably 90% by mass to 100% by mass with respect to the content of all ethylenically unsaturated compounds included in the photosensitive composition layer.

In a case where the photosensitive composition layer includes the ethylenically unsaturated compound having an acid group (preferably, the bi- or higher functional ethylenically unsaturated compound having a carboxy group or the carboxylic acid anhydride thereof), the content of the ethylenically unsaturated compound having an acid group is preferably 1% by mass to 50% by mass, more preferably 1% by mass to 20% by mass, and still more preferably 1% by mass to 10% by mass with respect to the total mass of the photosensitive composition layer.

—Polymerization Initiator—

It is preferable that the photosensitive composition layer includes a polymerization initiator.

Examples of the polymerization initiator include a thermal polymerization initiator and a photopolymerization initiator, and a photopolymerization initiator is preferable.

Examples of the photopolymerization initiator include a photopolymerization initiator having an oxime ester structure (hereinafter also referred to as an “oxime-based photopolymerization initiator”), a photopolymerization initiator having an α-aminoalkylphenone structure (hereinafter also referred to as an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure (hereinafter also referred to as an “acylphosphine oxide-based photopolymerization initiator”), and a photopolymerization initiator having an N-phenylglycine structure (hereinafter also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs [0031] to [0042] of JP2011-095716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methyl-1-pentanone-1-(O-acetyloxim e) [product name: IRGACURE (registered trademark) OXE-04, manufactured by BASF SE], 2-(dimethylamino)-2-[(4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE 651, manufactured by BASF SE], an oxime ester-based compound [product name: Lunar (registered trademark) 6, manufactured by DKSH Management Ltd.], (1-(biphenyl-4-yl)-2-methyl-2-morpholinopropan-1-one [product name APi-307 (registered trademark), manufactured by Shenzhen UV-ChemTech Co., Ltd.], 1-[4-(phenylthio)phenyl]-3-cyclopentylpropan-1,2-dione-2-(O-benzoyloxime) [product name: TR-PBG-305, manufactured by TRONLY), 3-cyclohexyl-1-[9-ethyl-6-(2-furanylcarbonyl)-9H-carbazole-3-yl]-, 1,2-propanedione-2-(O-acetyloxime) [product name: TR-PBG-326, manufactured by TRONLY], and 3-cyclohexyl-1-(6-(2-(benzoyloxyimino)hexanoyl)-9-ethyl-9H-carbazole-3-yl)-propan-1,2-dio ne-2-(O-benzoyloxime) [product name: TR-PBG-391, manufactured by TRONLY].

The photosensitive composition layer may include only one kind of photopolymerization initiator, or may include two or more kinds of photopolymerization initiators.

A content of the photopolymerization initiators is preferably 0.1% by mass or more, and more preferably 0.5% by mass or more with respect to the total mass of the photosensitive composition layer. In addition, the upper limit of the content of the photopolymerization initiator is preferably 10% by mass or less, and more preferably 5% by mass or less with respect to the total mass of the photosensitive composition layer.

—Alkali-Soluble Resin—

The photosensitive composition layer may include an alkali-soluble resin. The alkali-soluble resin is not particularly limited. Examples thereof include an acrylic resin, a phenol resin, an epoxy resin, a polyimide resin, a polybenzoxazole resin, and a polystyrene resin, and among these, an acrylic resin is preferable.

—Alkali-Soluble Acrylic Resin—

The photosensitive composition layer may include an alkali-soluble acrylic resin.

Since the photosensitive composition layer includes the alkali-soluble acrylic resin, the solubility of the photosensitive composition layer (non-exposed portion) in a developer is improved.

In the present disclosure, “alkali-soluble” means that a dissolution rate obtained by the following method is 0.01 μm/sec or more.

A propylene glycol monomethyl ether acetate solution in which a concentration of a target compound (for example, a resin) is 25% by mass is applied to a glass substrate, and then heated in an oven at 100° C. for 3 minutes to form a coating film (thickness of 2.0 μm) of the compound. The above-described coating film is immersed in a 1% by mass aqueous solution of sodium carbonate (liquid temperature of 30° C.), thereby obtaining the dissolution rate (μm/sec) of the above-described coating film.

In a case where the target compound is not dissolved in propylene glycol monomethyl ether acetate, the target compound is dissolved in an organic solvent other than propylene glycol monomethyl ether acetate (for example, tetrahydrofuran, toluene, or ethanol), which has a boiling point of lower than 200° C.

The alkali-soluble acrylic resin is not limited as long as it is the alkali-soluble acrylic resin described above. Here, “acrylic resin” means a resin containing at least one of a constitutional unit derived from a (meth)acrylic acid or a constitutional unit derived from a (meth)acrylic acid ester.

A total ratio of the constitutional unit derived from a (meth)acrylic acid and the constitutional unit derived from a (meth)acrylic acid ester in the alkali-soluble acrylic resin is preferably 30% by mole or more, and more preferably 50% by mole or more.

In the present disclosure, in a case where the content of “constitutional unit” is specified by mole fraction (molar proportion), the “constitutional unit” is synonymous with “monomer unit” unless otherwise specified. In addition, in the present disclosure, in a case where a resin or polymer has two or more specific constitutional units, the content of the specific constitutional units indicates the total content of the two or more specific constitutional units unless otherwise specified.

From the viewpoint of developability, the alkali-soluble acrylic resin preferably has a carboxy group. Examples of a method for introducing the carboxy group into the alkali-soluble acrylic resin include a method of synthesizing an alkali-soluble acrylic resin using a monomer having a carboxy group. By the method, the monomer having a carboxy group is introduced into the alkali-soluble acrylic resin as a constitutional unit having a carboxy group. Examples of the monomer having a carboxy group include acrylic acid and methacrylic acid.

The alkali-soluble acrylic resin may have one carboxy group or two or more carboxy groups. In addition, the alkali-soluble acrylic resin may have only one kind of constitutional unit having a carboxy group, or may have two or more kinds of constitutional units having a carboxy group.

A content of the constitutional unit having a carboxy group is preferably 5% by mole to 50% by mole, more preferably 5% by mole to 40% by mole, and still more preferably 10% by mole to 30% by mole with respect to the total amount of the alkali-soluble acrylic resin.

From the viewpoint of moisture permeability and hardness after curing, the alkali-soluble acrylic resin preferably has a constitutional unit having an aromatic ring. The constitutional unit having an aromatic ring is preferably a constitutional unit derived from a styrene compound.

Examples of a monomer which forms the constitutional unit having an aromatic ring include a monomer forming a constitutional unit derived from a styrene compound and benzyl (meth)acrylate.

Examples of the monomer forming a constitutional unit derived from a styrene compound include styrene, p-methyl styrene, α-methyl styrene, α,p-dimethylstyrene, p-ethylstyrene, p-t-butylstyrene, t-butoxystyrene, and 1,1-diphenylethylene, and styrene or α-methylstyrene is preferable and styrene is more preferable.

The alkali-soluble acrylic resin may have only one kind of constitutional unit having an aromatic ring, or two or more kinds of constitutional units having an aromatic ring.

In a case where the alkali-soluble acrylic resin has a constitutional unit having an aromatic ring, a content of the constitutional unit having an aromatic ring is preferably 5% by mole to 90% by mole, more preferably 10% by mole to 90% by mole, and still more preferably 15% by mole to 90% by mole with respect to the total amount of the alkali-soluble acrylic resin.

The alkali-soluble acrylic resin can include a constitutional unit having a chain structure. The chain structure may be linear or branched.

From the viewpoint of tackiness and hardness after curing, the alkali-soluble acrylic resin preferably includes a constitutional unit having an aliphatic cyclic skeleton.

An aliphatic ring in the aliphatic cyclic skeleton may be monocyclic or polycyclic, and examples thereof include a dicyclopentane ring, a cyclohexane ring, an isoborone ring, and a tricyclodecane ring. Among these, a tricyclodecane ring is preferable as the aliphatic ring in the aliphatic cyclic skeleton.

Examples of a monomer that forms the constitutional unit having an aliphatic cyclic skeleton include dicyclopentanyl (meth)acrylate, cyclohexyl (meth)acrylate, and isobornyl (meth)acrylate.

The alkali-soluble acrylic resin may have only one kind of constitutional unit having an aliphatic cyclic skeleton, or two or more kinds of the constitutional units.

In a case where the alkali-soluble acrylic resin has a constitutional unit having an aliphatic cyclic skeleton, a content of the constitutional unit having an aliphatic cyclic skeleton is preferably 5% by mole to 90% by mole, more preferably 10% by mole to 80% by mole, and still more preferably 10% by mole to 70% by mole with respect to the total amount of the alkali-soluble acrylic resin.

From the viewpoint of tackiness and hardness after curing, the alkali-soluble acrylic resin preferably has a reactive group.

As the reactive group, a radically polymerizable group is preferable, and an ethylenically unsaturated group is more preferable. In addition, in a case where the alkali-soluble acrylic resin has an ethylenically unsaturated group, the alkali-soluble acrylic resin preferably has a constitutional unit having an ethylenically unsaturated group in a side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryloyl group or a (meth)acryloxy group, and more preferably a (meth)acryloxy group.

The alkali-soluble acrylic resin may have only one kind of constitutional unit having an ethylenically unsaturated group, or two or more kinds of the constitutional units.

In a case where the alkali-soluble acrylic resin has a constitutional unit having an ethylenically unsaturated group, a content of the constitutional unit having an ethylenically unsaturated group is preferably 5% by mole to 70% by mole, more preferably 10% by mole to 50% by mole, and still more preferably 15% mole to 40% by mole with respect to the total amount of the alkali-soluble acrylic resin.

Examples of a method for introducing the reactive group into the alkali-soluble acrylic resin include a method of reacting an epoxy compound, a blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, a sulfo group, and the like.

Preferred examples of the method for introducing the reactive group into the alkali-soluble acrylic resin include a method in which an alkali-soluble acrylic resin having a carboxy group is synthesized by a polymerization reaction, and then a glycidyl (meth)acrylate is reacted with a part of the carboxy group of the alkali-soluble acrylic resin by a polymer reaction, thereby introducing a (meth)acryloxy group into the alkali-soluble acrylic resin. By the above-described method, an alkali-soluble acrylic resin having a (meth)acryloxy group in the side chain can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. In addition, the above-described polymer reaction is preferably carried out under a temperature condition of 80° C. to 110° C. In the above-described polymer reaction, it is preferable to use a catalyst such as an ammonium salt.

A weight-average molecular weight (Mw) of the alkali-soluble acrylic resin is preferably 10,000 or more, more preferably 10,000 to 100,000, and still more preferably 15,000 to 50,000.

From the viewpoint of developability, an acid value of the alkali-soluble acrylic resin is preferably 50 mgKOH/g or more, more preferably 60 mgKOH/g or more, still more preferably 70 mgKOH/g or more, and particularly preferably 80 mgKOH/g or more. In the present disclosure, the acid value of the alkali-soluble acrylic resin is a value measured according to the method described in JIS K0070: 1992.

From the viewpoint of preventing the exposed photosensitive composition layer (exposed portion) from dissolving in a developer, the upper limit of the acid value of the alkali-soluble acrylic resin is preferably 200 mgKOH/g or less, and more preferably 150 mgKOH/g or less.

Specific examples of the alkali-soluble acrylic resin are shown below. Furthermore, a content ratio (molar ratio) of each constitutional unit in the following alkali-soluble acrylic resins can be appropriately set within the above-described preferred range of Mw according to the purpose.

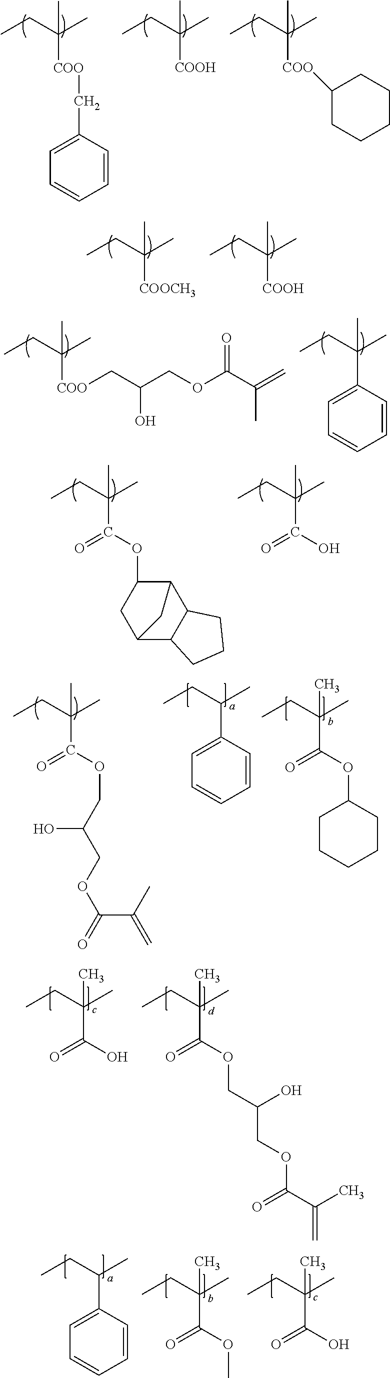

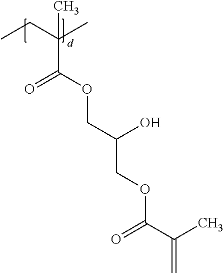

The photosensitive composition layer may include only one kind of alkali-soluble acrylic resin, or may include two or more kinds of alkali-soluble acrylic resins.

From the viewpoint of developability, a content of the alkali-soluble acrylic resin is preferably 10% by mass to 90% by mass, more preferably 20% by mass to 80% by mass, and still more preferably 25% by mass to 70% by mass with respect to the total mass of the photosensitive composition layer.

—Polymer including Constitutional Unit having Carboxylic Acid Anhydride Structure—

The photosensitive composition layer may further include, as the binder, a polymer (hereinafter, also referred to as a “polymer B”) including a constitutional unit having a carboxylic acid anhydride structure. In a case where the photosensitive composition layer contains the polymer B, the developability and the hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5-membered ring to 7-membered ring, more preferably a 5-membered ring or a 6-membered ring, and still more preferably a 5-membered ring.

The constitutional unit having a carboxylic acid anhydride structure is preferably a constitutional unit including a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

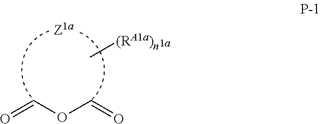

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s may be the same or different from each other. In addition, the plurality of R^{A1a}'s may be bonded to each other to form a ring, but it is preferable that they are not bonded to each other to form a ring.

As the constitutional unit having a carboxylic acid anhydride structure, a constitutional unit derived from an unsaturated carboxylic acid anhydride is preferable, a constitutional unit derived from an unsaturated cyclic carboxylic acid anhydride is more preferable, a constitutional unit derived from an unsaturated aliphatic carboxylic acid anhydride is still more preferable, a constitutional unit derived from maleic acid anhydride or itaconic acid anhydride is particularly preferable, and a constitutional unit derived from maleic acid anhydride is the most preferable.

The polymer B may have only one kind of constitutional unit having a carboxylic acid anhydride structure, or two or more kinds thereof.

A content of the constitutional unit having a carboxylic acid anhydride structure is preferably 0% by mole to 60% by mole, more preferably 5% by mole to 40% by mole, and still more preferably 10% by mole to 35% by mole with respect to the total amount of the polymer B.

The photosensitive composition layer may include only one kind of polymer B, or may include two or more kinds of polymers B.

In a case where the photosensitive composition layer includes the polymer B, from the viewpoint of the developability and the hardness after curing, a content of the polymer B is preferably 0.1% by mass to 30% by mass, more preferably 0.2% by mass to 20% by mass, still more preferably 0.5% by mass to 20% by mass, and particularly preferably 1% to 20% by mass with respect to the total mass of the photosensitive composition layer.

—Surfactant—

The photosensitive composition layer can include a surfactant.

Examples of the surfactant include the surfactants described in paragraph [0017] of JP4502784B and paragraphs [0060] to [0071] of JP2009-237362A.

Examples of the surfactant include a fluorine-based surfactant, a silicon-based surfactant (also referred to as a silicone-based surfactant), and a nonionic surfactant, and a fluorine-based surfactant or a silicone-based surfactant is preferable.

Examples of a commercially available product of the fluorine-based surfactant include: MEGAFACE (registered trademark) F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, R-41, R-41-LM, R-01, R-40, R-40-LM, RS-43, TF-1956, RS-90, R-94, RS-72-K, and DS-21 (all manufactured by DIC Corporation); FLUORAD (registered trademark) FC430, FC431, and FC171 (all manufactured by Sumitomo 3M Ltd.); SURFLON (registered trademark) S-382, SC-101, SC-103, SC-104, SC-105, SC-1068, SC-381, SC-383, S-393, and KH-40 (all manufactured by Asahi Glass Co., Ltd.); PolyFox (registered trademark) PF636, PF656, PF6320, PF6520, and PF7002 (all manufactured by OMNOVA Solutions Inc.); and FTERGENT (registered trademark) 710FM, 610FM, 601AD, 601ADH2, 602A, 215M, and 245F (all manufactured by NEOS Co., Ltd.).

As the fluorine-based surfactant, an acrylic compound which has a molecular structure having a functional group containing a fluorine atom and in which the functional group containing a fluorine atom is broken to volatilize a fluorine atom by applying heat to the molecular structure can also be suitably used. Examples of such a fluorine-based surfactant include MEGAFACE (registered trademark) DS series manufactured by DIC Corporation (The Chemical Daily (Feb. 22, 2016) and Nikkei Business Daily (Feb. 23, 2016)), for example, MEGAFACE (registered trademark) DS-21.

As the fluorine-based surfactant, a polymer of a fluorine atom-containing vinyl ether compound having a fluorinated alkyl group or a fluorinated alkylene ether group, and a hydrophilic vinyl ether compound can also be preferably used.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably an ethyleneoxy group and a propyleneoxy group) can be preferably used.

As the fluorine-based surfactant, a fluorine-containing polymer having an ethylenically unsaturated bond-containing group in the side chain can be used. Examples thereof include MEGAFACE (registered trademark) RS-101, RS-102, RS-718K, and RS-72-K (all manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the silicone-based surfactant include a linear polymer consisting of a siloxane bond and a modified siloxane polymer with an organic group introduced in the side chain or the terminal.

Specific examples of a commercially available product of the silicone-based surfactant include DOWSIL (registered trademark) 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all manufactured by Shin-Etsu Chemical Co., Ltd.), F-4440, TSF-4300, TSF-4445, TSF-4460, and TSF-4452 (all manufactured by Momentive Performance Materials Co., Ltd.), and BYK307, BYK323, and BYK330 (all manufactured by BYK Chemie).

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC (registered trademark) L10, L31, L61, L62, 10R5, 17R2, and 25R2 (all manufactured by BASF SE), TETRONIC (registered trademark) 304, 701, 704, 901, 904, and 150R1 (all manufactured by BASF SE), SOLSPERSE (registered trademark) 20000 (manufactured by The Lubrizol Corporation), NCW-101, NCW-1001, and NCW-1002 (all manufactured by FUJIFILM Wako Pure Chemical Corporation), PIONIN (registered trademark) D-6112, D-6112-W, and D-6315 (all manufactured by Takemoto Oil&Fat Co., Ltd.), and OLFINE E1010 and SURFYNOL 104, 400, and 440 (all manufactured by Nissin Chemical Co., Ltd.).

The photosensitive composition layer may include only one kind of surfactant, or may include two or more kinds of surfactants.

In a case where the photosensitive composition layer includes the surfactant, a content of the surfactant is preferably 0.01% by mass to 3% by mass, more preferably 0.05% by mass to 1% by mass, and still more preferably 0.1% by mass to 0.8% by mass with respect to the total mass of the photosensitive composition layer.

—Other Components—

The photosensitive composition layer may include a component other than the above-described components (hereinafter also referred to as “other components”). Examples of the other components include a heterocyclic compound (for example, an imidazole compound, a triazole compound, and a tetrazole compound), an aliphatic thiol compound, a blocked isocyanate compound, a hydrogen donating compound, particles (for example, metal oxide particles), and a colorant.

In addition, examples of the other components include a thermal polymerization inhibitor described in paragraph [0018] of JP4502784B and other additives described in paragraphs [0058] to [0071] of JP2000-310706A.

The photosensitive composition layer can be formed by drying a coating layer consisting of a coating liquid for forming the above-described photosensitive composition layer. The formation of the photosensitive composition layer will be described in detail in the section of transfer material.

—Thickness of Photosensitive Composition Layer—

A thickness of the photosensitive composition layer is not particularly limited, but is preferably 10.0 μm or less, and from the viewpoint of more excellent connection reliability between transparent conductive portions, more preferably 8.0 μm or less, still more preferably 5.0 μm or less, and particularly preferably 3.5 μm or less.

The lower limit of the thickness of the photosensitive composition layer is not limited. As the thickness of the photosensitive composition layer is smaller, the bend resistance can be improved. From the viewpoint of manufacturing suitability, the lower limit of the thickness of the photosensitive composition layer is preferably 0.05 μm or more. From the viewpoint of improving protective property of the transparent conductive portion, the lower limit of the thickness of the photosensitive composition layer is preferably 0.5 μm or more, and more preferably 1.1 μm or more.

For the thickness of the photosensitive composition layer, an arithmetic mean value of measured values at any five points, which are measured by observing a cross section of the photosensitive composition layer with a scanning electron microscope (SEM), is adopted.

—Refractive Index of Photosensitive Composition Layer—

A refractive index of the photosensitive composition layer is preferably 1.41 to 1.59, more preferably 1.47 to 1.56, and particularly preferably 1.49 to 1.54.

—Tint of Photosensitive Composition Layer—

The photosensitive composition layer is preferably achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

—Impurities of Photosensitive Composition Layer—

From the viewpoint of improving reliability and patterning properties, it is preferable that the photosensitive composition layer has a low content of impurities.

Specific examples of the impurities include sodium, potassium, magnesium, calcium, iron, manganese, copper, aluminum, titanium, chromium, cobalt, nickel, zinc, tin, ions of these, and halide ions (chloride ion, bromide ion, iodide ion, and the like). Among these, since the sodium ion, potassium ion, and chloride ion are easily mixed as impurities, the following content is particularly preferable.

The content of impurities in each layer is preferably 1,000 ppm or less, more preferably 200 ppm or less, and particularly preferably 40 ppm or less on a mass basis. The lower limit may be 0.01 ppm or more or 0.1 ppm or more on a mass basis.

Examples of a method for reducing the impurities to the above-described range include selecting a raw material of each layer containing no impurities, preventing the impurities from being mixed in a case of forming the layer, and washing and removing the impurities. By such a method, the amount of impurities can be kept within the range.

The impurities can be quantified by a known method such as inductively coupled plasma (ICP) emission spectroscopy, atomic absorption spectroscopy, and ion chromatography.

In addition, it is preferable that the content of compounds such as benzene, formaldehyde, trichloroethylene, 1,3-butadiene, carbon tetrachloride, chloroform, N,N-dimethylformamide, N,N-dimethylacetamide, and hexane is low in the photosensitive composition layer. The content of these compounds in each layer is preferably 1,000 ppm or less, more preferably 200 ppm or less, and particularly preferably 40 ppm or less on a mass basis. Although the lower limit is not particularly defined, from the viewpoint of the limit that can be reduced realistically and the limit of measurement, the lower limit may be 10 ppb or more or 100 ppb or more on a mass basis.

The content of compounds as impurities can be suppressed in the same manner as in the above-described metal as impurities. In addition, the compounds can be quantified by a known measurement method.

The photosensitive composition layer has been described above, but the patterned cured layer formed from the photosensitive composition layer also preferably has the same amount of impurities.

—Residual Monomer of Photosensitive Composition Layer—

The photosensitive composition layer may include residual monomers of each constitutional unit of the above-described alkali-soluble resin.

From the viewpoint of patterning properties and reliability, a content of the residual monomers is preferably 5,000 ppm by mass or less, more preferably 2,000 ppm by mass or less, and still more preferably 500 ppm by mass or less with respect to the total mass of the alkali-soluble resin. The lower limit is not particularly limited, but is preferably 1 ppm by mass or more and more preferably 10 ppm by mass or more.

From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less with respect to the total mass of the photosensitive composition layer. The lower limit is not particularly limited, but is preferably 0.1 ppm by mass or more and more preferably 1 ppm by mass or more.

It is preferable that an amount of residual monomers of the monomers in a case of synthesizing the alkali-soluble resin by a polymer reaction is also within the range. For example, in a case where glycidyl acrylate is reacted with a carboxylic acid side chain to synthesize the alkali-soluble resin, a content of glycidyl acrylate is preferably within the range.

The amount of the residual monomers can be measured by a known method such as liquid chromatography and gas chromatography.

<Transmittance of Photosensitive Composition Layer>

A visible light transmittance of the photosensitive composition layer at a film thickness of approximately 1.0 μm is preferably 80% or more, more preferably 90% or more, and most preferably 95% or more.

As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above.

Examples of a preferred value of the transmittance include 87%, 92%, and 98%.

The same applies to a transmittance of the cured film of the photosensitive composition layer at a film thickness of approximately 1 μm, and a preferred aspect thereof is also the same.

<Moisture Permeability of Photosensitive Composition Layer>

From the viewpoint of rust preventive property of electrode or wiring line, and viewpoint of device reliability, a moisture permeability of the pattern obtained by curing the photosensitive composition layer (cured film of the photosensitive composition layer) at a film thickness of 40 μm is preferably 500 g/m²·24 hr or less, more preferably 300 g/m²·24 hr or less, and still more preferably 100 g/m²·24 hr or less.

The moisture permeability is measured using a cured film by curing the photosensitive composition layer by exposing the photosensitive composition layer with an i-line at an exposure amount of 300 mJ/cm² and then performing post-baking at 145° C. for 30 minutes.

The moisture permeability is measured according to a cup method of JIS Z0208:1976. It is preferable that the above-described moisture permeability is as above under any test conditions of temperature 40° C. and humidity 90%, temperature 65° C. and humidity 90%, or temperature 80° C. and humidity 95%.

Examples of a specific preferred numerical value include 80 g/m²·24 hr, 150 g/m²·24 hr, and 220 g/m²·24 hr.

<Dissolution Rate of Photosensitive Composition Layer>

From the viewpoint of suppressing residue during development, a dissolution rate of the photosensitive composition layer in a 1.0% sodium carbonate aqueous solution is preferably 0.01 μm/sec or more, more preferably 0.10 μm/sec or more, and still more preferably 0.20 μm/sec or more.

From the viewpoint of edge shape of the pattern, it is preferable to be 5.0 μm/sec or less, more preferable to be 4.0 μm/sec or less, and still more preferable to be 3.0 μm/sec or less.

Examples of a specific preferred numerical value include 1.8 μm/sec, 1.0 μm/sec, and 0.7 μm/sec.

The dissolution rate of the photosensitive composition layer in the 1.0% by mass sodium carbonate aqueous solution per unit time is measured as follows.

A photosensitive composition layer (within a film thickness of 1.0 μm to 10 μm) formed on a glass substrate, from which the solvent has been sufficiently removed, is subjected to a shower development with a 1.0% by mass sodium carbonate aqueous solution at 25° C. until the photosensitive composition layer is dissolved completely (however, the maximum developing time is 2 minutes). The dissolution rate of the photosensitive composition layer is obtained by dividing the film thickness of the photosensitive composition layer by the time required for the photosensitive composition layer to dissolve completely. In a case where the photosensitive layer is not dissolved completely in 2 minutes, the dissolution rate of the photosensitive layer is calculated in the same manner as above, from the amount of change in film thickness up to 2 minutes.

A dissolution rate of the cured film (within a film thickness of 1.0 μm to 10 μm) of the photosensitive composition layer in a 1.0% by mass sodium carbonate aqueous solution is preferably 3.0 μm/sec or less, more preferably 2.0 μm/sec or less, still more preferably 1.0 μm/sec or less, and most preferably 0.2 μm/sec or less. The cured film of the above-described photosensitive composition layer is a film obtained by exposing the photosensitive composition layer with i-rays at an exposure amount of 300 mJ/cm².

Examples of a specific preferred numerical value include 0.8 μm/sec, 0.2 μm/sec, and 0.001 μm/sec.

As the development conditions, a shower nozzle of ¼ MINJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

<Swelling Ratio of Photosensitive Composition Layer>

From the viewpoint of improving pattern forming properties, a swelling ratio of the photosensitive composition layer after exposure with respect to a 1.0% by mass sodium carbonate aqueous solution is preferably 100% or less, more preferably 50% or less, and still more preferably 30% or less.

The swelling ratio of the photosensitive composition layer after exposure with respect to a 1.0% by mass sodium carbonate aqueous solution is measured as follows.

A photosensitive composition layer (within a film thickness of 1.0 μm to 10 μm) formed on a glass substrate, from which the solvent has been sufficiently removed, is exposed at an exposure amount of 500 mJ/cm² (i-ray measurement) with an ultra-high pressure mercury lamp. The glass substrate is immersed in a 1.0% by mass sodium carbonate aqueous solution at 25° C., and the film thickness is measured after 30 seconds. Then, an increased proportion of the film thickness after immersion to the film thickness before immersion is calculated.

Examples of a specific preferred numerical value include 4%, 13%, and 25%.

<Foreign Substance in Photosensitive Composition Layer>

From the viewpoint of pattern forming properties, the number of foreign substances having a diameter of 1.0 μm or more in the photosensitive composition layer is preferably 10 pieces/mm² or less, and more preferably 5 pieces/mm² or less.

The number of foreign substances is measured as follows.

Any 5 regions (1 mm×1 mm) on a surface of the photosensitive composition layer are visually observed from a normal direction of the surface of the photosensitive composition layer with an optical microscope, the number of foreign substances having a diameter of 1.0 μm or more in each region is measured, and the values are arithmetically averaged to calculate the number of foreign substances.

Examples of a specific preferred numerical value include 0 pieces/mm², 1 pieces/mm², 4 pieces/mm², and 8 pieces/mm².

<Haze of Dissolved Substance in Photosensitive Composition Layer>

From the viewpoint of suppressing generation of aggregates during development, a haze of a solution obtained by dissolving 1.0 cm³ of the photosensitive composition layer in 1.0 liter of a 1.0% by mass sodium carbonate aqueous solution at 30° C. is preferably 60% or less, more preferably 30% or less, still more preferably 10% or less, and most preferably 1% or less.

The above-described haze is measured as follows.

First, a 1.0% by mass sodium carbonate aqueous solution is prepared, and a liquid temperature is adjusted to 30° C. 1.0 cm³ of the photosensitive composition layer is added to 1.0 L of the sodium carbonate aqueous solution. The solution is stirred at 30° C. for 4 hours, being careful not to mix air bubbles. After stirring, the haze of the solution in which the photosensitive composition layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm.

Examples of a specific preferred numerical value include 0.4%, 1.0%, 9%, and 24%.

(Refractive Index-Adjusting Layer)

The above-described laminate precursor may have a constituent element other than the base material, the first transparent conductive portion, and the photosensitive composition layer.

For example, the laminate precursor obtained in the step 1 may have a refractive index-adjusting layer on the first transparent conductive portion. The laminate precursor may have a refractive index-adjusting layer between the photosensitive composition layer and the first transparent conductive portion.

(Scattering Layer)

In addition, the above-described laminate precursor may have the scattering layer having a diffuse transmittance of 5% or more, which is described in the step 2.

It is preferable that the above-described scattering layer in the above-described laminate precursor is provided on the side of the above-described photosensitive composition layer opposite to the side on which the above-described base material is provided.

The scattering layer of the above-described laminate precursor is the same as the scattering layer described in the step 2, and the preferred aspect thereof is also the same.

In a case where the photosensitive composition layer is formed of the transfer material, it is preferable that the transfer material further has a scattering layer having a diffuse transmittance of 5% or more between the temporary support and the photosensitive composition layer, and in the above-described transfer, the photosensitive composition layer and the scattering layer are transferred.

<Touch Panel Sensor>

A touch panel sensor according to an embodiment of the present disclosure has, in the following order a base material, a first transparent conductive portion, a cured layer having a contact hole, and a second transparent conductive portion, in which a taper angle of the contact hole in the cured layer with respect to a surface direction of the base material in a cross section parallel to a normal direction of the base material is 50° or less.

In addition, a method for producing the touch panel sensor according to the embodiment of the present disclosure is preferably a method including the method for producing a laminate according to the embodiment of the present disclosure.

The method for measuring the taper angle is as described above.

The taper angle of the contact hole in the touch panel sensor according to the embodiment of the present disclosure with respect to the surface direction of the base material is 50° or less, preferably 40° or less and more preferably 30° or less.

The lower limit of the taper angle is not particularly limited, but in consideration of the function as the contact hole, may be 10° or more.

Since the touch panel sensor according to the embodiment of the present disclosure has a transparent conductive film having the layer configuration as shown in FIG. 1, the contact hole 22 formed by the patterned cured layer 16A formed on the first transparent conductive portion has a gentle inclination on the side surface. Therefore, as compared with a touch panel sensor having a contact hole with a steep side surface, occurrence of disconnection during the formation of the second transparent conductive portion 18 and entrainment of undesirable air bubbles during the formation of the transparent resin protective layer are suppressed. Further, visibility of the contact hole due to reflection is improved, resulting in a touch panel sensor with a better appearance.

### EXAMPLES

Hereinafter, the present disclosure will be described more specifically with Examples. However, the present disclosure is not limited to the following examples as long as it does not exceed the gist of the present disclosure.

Unless otherwise specified, in the following examples, “%” and “part” are based on mass. “Mw” means a weight-average molecular weight.

### Example 1

A cycloolefin resin film having a film thickness of 38 μm and a refractive index of 1.53 was subjected to a corona discharge treatment for 3 seconds under the conditions of an electrode length of 240 mm, and a distance between work electrodes of 1.5 mm at an output voltage of 100% and an output of 250 W with a wire electrode having a diameter of 1.2 mm by using a high frequency oscillator, to carry out the surface reforming, thereby obtaining a transparent base material.

Next, a material shown in Table 1 was coated on a corona discharge-treated surface of the transparent base material using a slit-shaped nozzle, irradiated with ultraviolet rays (integrated light amount of 300 mJ/cm²), and dried at approximately 110° C. to form a transparent film having a refractive index of 1.60 and a film thickness of 80 nm.

TABLE

| Raw material | Material-C |
|---|---|
| ZrO₂: ZR-010 manufactured by SOLAR CO., LTD. | 2.08 |
| DPHA solution (dipentaerythritol hexaacrylate: 38%, dipentaerythritol pentaacrylate: | 0.29 |
| 38%, 1-methoxy-propyl acetate: 24%) | |
| Urethane-based monomer: UK Oligo UA-32P, manufactured by Shin-Nakamura | 0.14 |
| Chemical Co., Ltd.; non-volatile content: 75%, 1-methoxy-propyl acetate: 25% | |
| Monomer mixture (polymerizable compound (b2-1) described in paragraph [0111] | 0.36 |
| of JP2012-78528A, n = 1; content of tripentaerythritol octaacrylate: 85%, sum of | |
| n = 2 and n = 3 as impurities: 15%) | |
| Polymer solution 1 (structural formula P-25 described in paragraph [0058] of | 1.89 |
| JP2008-146018A; weight-average molecular weight = 35,000, solid content: 45%, | |
| 1-methoxy-propyl acetate: 15%, 1-methoxy-propanol: 40%) | |
| Photoradical polymerization initiator: 2-benzyl-2-dimethylamino-1-(4- | 0.03 |
| morpholinophenyl)butanone (Irgacure (resitered trademark) 379, manufactured | |
| by BASF SE) | |
| Photopolymerization initator: KAYACURE DETX-S (manufactured by Nippon | 0.03 |
| Kayaku Co., Ltd., alkylthioxanthone) | |
| Polymer solution 2 (polymer having structural formula represented by Formula (3); | 0.01 |
| solution of weight-average molecular weight of 15000, non-volatile content: 30% | |
| by mass, methyl ethyl ketone: 70% by mass) | |
| 1-Methoxy-propyl acetate | 38.73 |
| Methyl ethyl ketone | 56.80 |
| Total (part by mass) | 100 |

Formual (3)

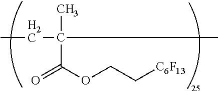

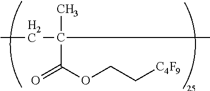

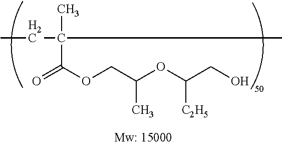

Next, a film in which the transparent film was formed on the transparent base material was introduced into a vacuum chamber, and an ITO thin film having a thickness of 40 nm and a refractive index of 1.82 was formed as a first transparent conductive portion on the transparent film, using an ITO target (indium:tin=95:5 (molar ratio)) having a SnO₂ content of 10% by mass, by a direct current (DC) magnetron sputtering (conditions: temperature of transparent base material: 150° C., argon pressure: 0.13 Pa, oxygen pressure: 0.01 Pa). A surface electrical resistance of the ITO thin film was 80Ω/□ (square per Ω).

Next, the ITO thin film was etched and patterned by a known chemical etching method to obtain a conductive substrate having a transparent film and a transparent conductive portion on the transparent base material.

(Preparation of Photosensitive Composition)

23.0 parts of a B-1 solution (polymer concentration: 36% by mass, solvent: 1-methoxy-2-propyl acetate) as a binder, 0.11 parts of a photopolymerization initiator (IRGACURE 379, manufactured by BASF SE), 0.11 parts of a photopolymerization initiator (IRGACURE 907, manufactured by BASF SE), 3.55 parts of a polymerizable compound (A-NOD-N, manufactured by Shin-Nakamura Chemical Co., Ltd.), 0.8 parts of a polymerizable compound (TO-2349, manufactured by Toagosei Co., Ltd.), 2.18 parts of a polymerizable compound (A-DPH, manufactured by Shin-Nakamura Chemical Co., Ltd.), 0.01 parts of a polymerization inhibitor (phenothiazine, manufactured by FUJIFILM Wako Pure Chemical Corporation), 0.04 parts of benzoimidazole (manufactured by Tokyo Chemical Industry Co., Ltd.), 0.16 parts of a surfactant (MEGAFACE F-551A, manufactured by DIC Corporation), and 20.2 parts of 1-methoxy-2-propyl acetate (manufactured by Showa Denko K. K.), 49.4 parts of methyl ethyl ketone (manufactured by SANKYO CHEMICAL CO., LTD.), and 0.43 parts of propylene glycol monomethyl ether (manufactured by Daicel Corporation) as solvents were mixed with each other, and the mixture was filtered through a filter with a pore diameter of 3 μm to prepare a photosensitive composition.

B-1 (hereinafter, the molar ratio of the repeating units in the formula was 40:15:25:20 in the order from the repeating unit on the left side, and Mw was 17,000)

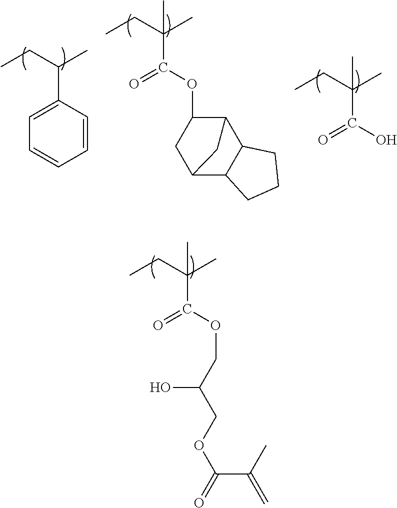

(Manufacturing of Transfer Film 1)

The photosensitive composition prepared above was applied to a temporary support of a polyethylene terephthalate film (16KS40: product name, manufactured by Toray Industries, Inc.) having a thickness of 16 μm using a slit-shaped nozzle, while the coating amount of the photosensitive composition was adjusted so that a thickness of a photosensitive composition layer after drying was 5 Next, the obtained temporary support was dried in a drying zone at 80° C. to form a photosensitive composition layer.

Next, a polyethylene terephthalate film (16KS40: product name, manufactured by Toray Industries, Inc.) having a thickness of 16 μm was pressure-bonded to a surface of the photosensitive composition layer as a protective film to manufacture a transfer film 1.

Next, the transfer film 1 was used to obtain an exposed laminate precursor having the layer configuration shown in FIG. 4.

That is, the protective film of the transfer film 1 manufactured above was peeled off, the exposed surface of the photosensitive composition layer 16 was brought into contact with a surface of the conductive base material 12, on which the first transparent conductive portion had been formed, and the photosensitive composition layer 16 and the temporary support 24 were laminated on the conductive base material 12 under the following conditions to obtain the laminate precursor having the layer configuration shown in FIG. 4.

(Conditions)

Temperature of transparent base material: 40° C.

Temperature of rubber roller: 110° C.

Linear pressure: 3 N/cm

Transportation speed: 2 m/min

Next, as shown in FIG. 4, the exposure mask 26 (mask for forming through hole: 50 μm×250 μm size) was closely attached to the surface of the temporary support 24 of the obtained laminate (surface of the transparent base material 12 on the photosensitive composition layer 16 side).

Thereafter, Lens shaping diffuser (registered trademark) LSD30ACUVT30 manufactured by OPTICAL SOLUTIONS (scattering angle: 30°, material: UV transparent acrylic resin) as the scattering layer 28 was disposed on the exposure mask 26. In Table 2, the scattering layer used in Example 1 was described as “Resin layer having irregularities”.

Using a proximity type exposure machine (manufactured by Hitachi High-Tech Electronics Engineering Co., Ltd.) having an ultra-high pressure mercury lamp as the exposure light source, through the scattering layer 28, the laminate having the exposure mask 26 was exposed in a patterned manner with i-rays at an exposure amount of 100 mJ/cm².

Thereafter, the exposure mask 26 and the temporary support 24 were peeled off from the exposed laminate precursor, and the peeled plane (surface) was developed for 60 seconds using a 1% by mass aqueous solution of sodium carbonate having a temperature of 30° C. After a washing treatment, the residue was further removed by injecting ultrapure water from an ultra-high pressure washing nozzle onto the peeled surface which had been developed. Thereafter, air was blown onto the peeled surface from which the residue had been removed to remove moisture, thereby obtaining a laminate having the patterned cured layer 16A.

### Example 2

A laminate having the patterned cured layer 16A was obtained in the same manner as in Example 1, except that the scattering layer was changed to a layer containing specific particles described below.

In Table 2, the scattering layer used in Example 2 was described as “Specific particles-containing layer”. The specific particles-containing layer is a layer having a thickness of 30 μm, in which polymethyl methacrylate (refractive index: 1.50) as the matrix material includes silica particles (Seahostar KE-P150 manufactured by NIPPON SHOKUBAI CO., LTD.; refractive index: 1.43) having an average primary particle diameter of 1.5 μm, which are the specific particles, in an amount of 15% by mass in terms of solid content with respect to the total amount of the specific particles-containing layer. In the scattering layer of Example 2, the difference in refractive index between the matrix material and the specific particles was 0.07, which was 0.05 or more.

### Comparative Example 1

A laminate having the patterned cured layer was obtained in the same manner as in Example 1, except that the pattern exposure was performed without the scattering layer.

### Examples 3 to 10

A laminate having the patterned cured layer was obtained in the same manner as in Example 1, except that the scattering layer was manufactured from the following.

Example 3: LSD60ACUVT30 (manufactured by OPTICAL SOLUTIONS, scattering angle: 60°, material: UV transparent acrylic resin, resin layer having irregularities, thickness: 760 μm)

Example 4: LIGHT-UP LDS (manufactured by KIMOTO, scattering angle: 30°, light diffusion polymer film, resin layer having irregularities, thickness: 115 μm)

Example 5: LIGHT-UP GM7 (manufactured by KIMOTO, scattering angle: 15°, light diffusion polymer film, resin layer having irregularities, thickness: 115 μm)

Example 6: LIGHT-UP MXE (manufactured by KIMOTO, scattering angle: 30°, light diffusion polymer film, resin layer having irregularities, thickness: 115 μm)

Example 7: SDXK-1FS (manufactured by SUNTECHOPT, scattering angle: 15°, light diffusion polymer film, resin layer having irregularities, thickness: 39 μm)

Example 8: HAA120 (manufactured by LINTEC Corporation, scattering angle: 25°, light diffusion polymer film, resin layer having refractive index distribution structure, thickness: 120 μm)

Example 9: Opalus PBS-689G (manufactured by KEIWA Inc., scattering angle: 30°, particles-containing light diffusion polymer film, specific particles-containing layer, thickness: 83 μm)

Example 10: Opalus UDD-247D2 (manufactured by KEIWA Inc., scattering angle: 30°, light diffusion polymer film, resin layer having irregularities, thickness: 51 μm)

[Evaluation]

(Measurement of Diffuse Transmittance of Scattering Layer)

In accordance with JIS K 7136 “Plastic—Method for obtaining haze of transparent material (2000)”, the diffuse transmittance was obtained using a haze meter NDH7000II of NIPPON DENSHOKU INDUSTRIES Co., Ltd. as a measuring device.

The results are shown in Table 2 below.

(Measurement of Scattering Angle of Scattering Layer)

Using a goniophotometer GP-200 manufactured by MURAKAMI COLOR RESEARCH LABORATORY CO., LTD., light was vertically incident on the scattering layer, and the intensity of the transmitted light was measured in an angle range from +90° to −90°. Full angular width at which the intensity was halved with respect to the intensity of 0° was defined as the scattering angle.

The results are shown in Table 2 below.

(Measurement of Taper Angle on Side Surface of Patterned Cured Layer)

The taper angle on the side surface of the patterned cured layer 16A formed in the obtained laminate was measured by the method described above.

The results are shown in Table 2 below.

(Presence or Absence of Disconnection of Second Transparent Conductive Portion)

Using a DC magnetron sputtering, an ITO conductive layer having a thickness of 100 nm was formed on the entire surface of the obtained laminate to form the second transparent conductive portion.

A cross section of the formed second transparent conductive portion was observed with a scanning electron microscope (SEM) to observe the presence or absence of disconnection.

The results are shown in Table 2 below.

| | | | | | | | | | | | Com- |
|---|---|---|---|---|---|---|---|---|---|---|---|
| | Example | Example | Example | Example | Example | Example | Example | Example | Example | Example | parative |
| | 1 | 2 | 3 | 4 | 5 | 6 | 7 | 8 | 9 | 10 | Example 1 |
| Scattering layer | Resin | Specific | Resin | Resin | Resin | Resin | Resin | Layer having | Specific | Resin | None |
| | layer | particle- | layer | layer | layer | layer | layer | refractive | particle- | layer | |
| | having | containing | having | having | having | having | having | index | containing | having | |
| | irregu- | layer | irregu- | irregu- | irregu- | irregu- | irregu- | distribution | layer | irregu- | |
| | larities | | larities | larities | larities | larities | larities | structure | | larities | |
| Diffuse | 95% | 90% | 95% | 95% | 95% | 95% | 90% | 83% | 90% | 90% | — |
| transmittance | | | | | | | | | | | |
| of scattering layer | | | | | | | | | | | |
| Scattering angle of | 30° | 30° | 60° | 30° | 15° | 30° | 15° | 25° | 30° | 30° | — |
| scattering layer | | | | | | | | | | | |
| (full angular width | | | | | | | | | | | |
| at half maximum) | | | | | | | | | | | |
| Taper angle | 30° | 35° | 10° | 30° | 35° | 30° | 35° | 40° | 30° | 30° | 75° |
| Disconnection of | N | N | N | N | N | N | N | N | N | N | Y |
| second transparent | | | | | | | | | | | |
| conductive layer | | | | | | | | | | | |

### Examples 11 to 42

—Preparation of Binder Polymer Solution—

Solutions containing the following B-2 to B-11 (concentration of solid contents: 36% by mass, solvent: 1-methoxy-2-propyl acetate) were prepared.

Details of B-2 to B-11 are shown below. The ratio of each monomer represents a mass ratio.

B-2: copolymer of MMA/MAA/St=40/16/44 (acid value: 104 mgKOH/g, Mw=17,000)

B-3: copolymer of MMA/MAA/CHMA=35/25/40 (acid value: 113 mgKOH/g, Mw=17,000)

B-4: copolymer of St/MMA/MAA/MAA-GMA=47/2/19/32 (acid value: 124 mgKOH/g, Mw=17,000)

B-5: copolymer of St/MMA/MAA/MAA-GMA/HEMA=45/2/19/32/2 (acid value: 124 mgKOH/g, Mw=17,000)

B-6: copolymer of St/MMA/MAA/MAA-GMA=47/2/19/32 (acid value: 124 mgKOH/g, Mw=42,000)

B-7: copolymer of St/MMA/MAA/MAA-GMA=47/2/19/32 (acid value: 124 mgKOH/g, Mw=61,000)

B-8: copolymer of St/MMA/MAA/MAA-GMA=47/2/19/32 (acid value: 124 mgKOH/g, Mw=105,000)

B-9: copolymer of St/MMA/MAA/MAA-GMA=53/2/13/32 (acid value: 83 mgKOH/g, Mw=17,000)

B-10: copolymer of St/MMA/MAA/MAA-GMA=44/2/22/32 (acid value: 143 mgKOH/g, Mw=17,000)

B-11: copolymer of St/BzMA/DCPMA/MAA-GMA/MMA/HEMA=15/15/17/19/32/1/1 (acid value: 124 mgKOH/g, Mw=25,000)

In addition, each monomer described in B-2 to B-11 is shown below.

St: styrene

MAA: methacrylic acid

MMA: methyl methacrylate

MMA-GMA: monomer obtained by adding glycidyl methacrylate to methacrylic acid

DCPMA: dicyclopentanyl methacrylate

CHMA: cyclohexyl methacrylate

HEMA: 2-hydroxyethyl methacrylate

BzMA: benzyl methacrylate

—Preparation of Composition for Forming Refractive Index-Adjusting Layer—

A composition for forming a refractive index-adjusting layer was prepared according to components and contents having the composition shown in Table 3. The unit of each numerical value in the column of composition in Table 3 represents “part by mass”.

TABLE 3

| | Raw material | Composition |
|---|---|---|
| ZrO₂ | NanoUse OZ-630M (manufactured by | 4.3 |
| particles | Nissan Chemical Corporation) | |
| Binder | Copolymer of methacrylic acid/allyl | 0.24 |
| | methacrylate = 40/60 (molar ratio) | |
| | Compound B | 0.01 |
| Monomer | TO-2349 (manufactured by | 0.03 |
| | Toagosei Co., Ltd.) | |
| Additive | Benzotriazole BT-LX (manufactured | 0.03 |
| | by Jouhoku Chemical industry) | |
| Surfactant | MEGAFACE F444 (manufactured | 0.01 |
| | by Daicel Corporation) | |
| Solvent | 25% by mass aqueous solution of ammonia | 7.82 |
| | Monoisopropanolamine (manufactured | 0.02 |
| | by MITSUI FINE CHEMICALS, INC.) | |
| | Ion exchange water | 21.5 |
| | Methanol | 66 |
| Total | | 100.0 |

In Table 3, “Compound B” is a polymer (weight-average molecular weight: 15,500) represented by the following structural formula. The value of the repeating unit in the formula is a molar ratio.

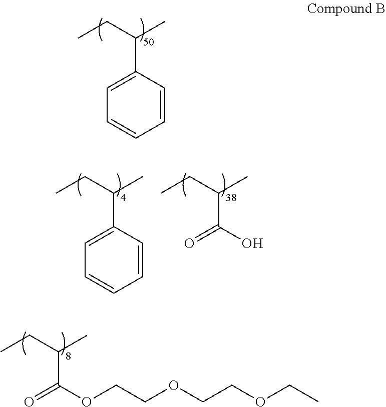

—Preparation of Composition for Forming Photosensitive Composition Layer—

In each example, photosensitive compositions were each prepared so that the photosensitive composition had the composition shown in Table 4 or Table 5.

—Manufacturing of Laminate—

The photosensitive composition shown in Table 4 or Table 5 was applied to the temporary support shown in Table 4 or Table 5 using a slit-shaped nozzle, while the amount was adjusted so that a film thickness after drying was as shown in Table 4 or Table 5, and then dried in a drying zone at 100° C. to obtain a photosensitive composition layer.

Thereafter, the composition for forming a refractive index-adjusting layer was applied thereto using a slit-shaped nozzle, while the amount was adjusted so that a film thickness after drying was as shown in Table 4 or Table 5, and then dried in a drying zone at 100° C. to obtain a refractive index-adjusting layer.

Next, a polyethylene terephthalate film (16KS40: product name, manufactured by Toray Industries, Inc.) having a thickness of 16 μm was pressure-bonded to a surface of the refractive index-adjusting layer as a protective film to manufacture a transfer film of each example. In Examples 33 to 36, the refractive index-adjusting layer was not formed.

A laminate having the patterned cured layer was obtained in the same manner as in Example 1, except that LIGHT-UP LDS (manufactured by KIMOTO) was used as the scattering layer for the transfer film of each example. The obtained laminate was used for the evaluations in the same manner as in Example 1.

| | | | Example | Example | Example | Example | Example | Example | Example | Example | Example | Example | Example | Example | Example | Example | Example | Example |
|---|---|---|---|---|---|---|---|---|---|---|---|---|---|---|---|---|---|---|
| | | Type | 11 | 12 | 13 | 14 | 15 | 16 | 17 | 18 | 19 | 20 | 21 | 22 | 23 | 24 | 25 | 26 |
| [symbol] | [symbol] | B-1 | 160.0 | — | — | — | — | — | — | — | — | — | 140.0 | [symbol] | [symbol] | [symbol] | — | — |
| [symbol] | [symbol] | B-2 | — | 160.0 | — | — | — | — | — | — | — | — | 10.0 | — | — | — | — | — |
| | | B-3 | — | — | 160.0 | — | — | — | — | — | — | — | — | — | — | — | — | — |
| | | B-4 | — | — | — | 160.0 | — | — | — | — | — | — | — | — | — | — | 160.0 | 160.0 |
| | | B-5 | — | — | — | — | 160.0 | — | — | — | — | — | — | 10.0 | — | — | — | — |
| | | B-6 | — | — | — | — | — | 160.0 | — | — | — | — | — | — | — | — | — | — |
| | | B-7 | — | — | — | — | — | — | 160.0 | — | — | — | — | — | — | — | — | — |
| | | B-8 | — | — | — | — | — | — | — | 160.0 | — | — | — | — | — | — | — | — |
| | | B-9 | — | — | — | — | — | — | — | — | 160.0 | — | — | — | — | — | — | — |
| | | B-10 | — | — | — | — | — | — | — | — | — | 160.0 | — | — | — | — | — | — |
| | [symbol] | A- [symbol] -N | [symbol] .9 | [symbol] .9 | [symbol] .9 | [symbol] .9 | [symbol] .9 | [symbol] .9 | [symbol] .9 | [symbol] .9 | [symbol] .9 | [symbol] .9 | 13.0 | 12.0 | [symbol] .9 | [symbol] .9 | [symbol] .9 | [symbol] .9 |
| | com- | R [symbol] | [symbol] .9 | [symbol] .9 | [symbol] .9 | [symbol] .9 | [symbol] .9 | [symbol] .9 | [symbol] .9 | [symbol] .9 | [symbol] .9 | [symbol] .9 | [symbol] | 6.0 | [symbol] .9 | [symbol] .9 | [symbol] .9 | [symbol] .9 |
| | pound | A-DCP | — | — | — | — | — | — | — | — | — | — | — | 6.0 | — | — | — | — |
| | | [symbol] | 4.3 | 4.3 | 4.3 | 4.3 | 4.3 | 4.3 | 4.3 | 4.3 | 4.3 | 4.3 | 4.3 | 4.0 | 4.3 | 4.3 | 4.3 | 4.3 |
| | | A-DPH | 11.1 | 11.1 | 11.1 | 11.1 | 11.1 | 11.1 | 11.1 | 11.1 | 11.1 | 11.1 | 11.1 | 11.1 | 11.1 | 11.1 | 11.1 | 11.1 |
| | [symbol] | [symbol] | 0.72 | 0.72 | 0.72 | 0.72 | 0.72 | 0.72 | 0.72 | 0.72 | 0.72 | 0.72 | 0.72 | 0.72 | 0.72 | 0.72 | 0.72 | 0.72 |
| | [symbol] | [symbol] | — | — | — | — | — | — | — | — | — | — | — | — | — | — | — | — |
| | | OXE-02 | | | | | | | | | | | | | | | | |
| | | [symbol] | — | — | — | — | — | — | — | — | — | — | — | — | — | — | — | — |
| | | OXE-03 | | | | | | | | | | | | | | | | |
| | | [symbol] 907 | — | — | — | — | — | — | — | — | — | — | — | — | — | — | — | — |
| | | AP [symbol] | 1.00 | 1.00 | 1.00 | 1.00 | 1.00 | 1.00 | 1.00 | 1.00 | 1.00 | 1.00 | 1.00 | 1.00 | 1.00 | 1.00 | 1.00 | 1.00 |
| | Poly [symbol] | [symbol] | — | — | — | — | — | — | — | — | — | — | — | — | — | — | — | — |
| | [symbol] | | | | | | | | | | | | | | | | | |
| | [symbol] | [symbol] | 0.04 | 0.04 | 0.04 | 0.04 | 0.04 | 0.04 | 0.04 | 0.04 | 0.04 | 0.04 | — | — | 0.04 | 0.04 | 0.04 | 0.04 |
| | | [symbol] | 2.00 | 2.00 | 2.00 | 2.00 | 2.00 | 2.00 | 2.00 | 2.00 | 2.00 | 2.00 | — | — | 2.00 | 2.00 | 2.00 | 2.00 |
| | | [symbol] | — | — | — | — | — | — | — | — | — | — | — | — | — | — | — | — |
| | | [symbol] | | | | | | | | | | | | | | | | |
| | | [symbol] | — | — | — | — | — | — | — | — | — | — | — | — | — | — | — | — |
| | | [symbol] | | | | | | | | | | | | | | | | |
| | [symbol] | F- [symbol] 51A | 0.16 | 0.16 | 0.16 | 0.16 | 0.16 | 0.16 | 0.16 | 0.16 | 0.16 | 0.16 | 0.16 | 0.16 | 0.16 | 0.16 | 0.16 | 0.16 |
| | Sol- | 1-Met | 300 | 300 | 300 | 300 | 300 | 300 | 300 | 300 | 300 | 300 | 300 | 300 | 300 | 300 | 300 | 300 |
| | vent | [symbol] | | | | | | | | | | | | | | | | |
| | | Meth | 300 | 300 | 300 | 300 | 300 | 300 | 300 | 300 | 300 | 300 | 300 | 300 | 300 | 300 | 300 | 300 |
| | | yl [symbol] | | | | | | | | | | | | | | | | |
| | | Propyl | 100 | 100 | 100 | 100 | 100 | 100 | 100 | 100 | 100 | 100 | 100 | 100 | 100 | 100 | 100 | 100 |
| | | glycol | | | | | | | | | | | | | | | | |
| | | mono- | | | | | | | | | | | | | | | | |
| | | methyl | | | | | | | | | | | | | | | | |
| | | ether | | | | | | | | | | | | | | | | |

| Layer thick- | | 3 μm | 3 μm | 3 μm | 3 μm | 3 μm | 3 μm | 3 μm | 3 μm | 3 μm | 3 μm | 3 μm | 3 μm | 5 μm | 8 μm | 5 μm | 8 μm |
|---|---|---|---|---|---|---|---|---|---|---|---|---|---|---|---|---|---|
| ness [symbol] of | | | | | | | | | | | | | | | | | |
| composition | | | | | | | | | | | | | | | | | |
| layer | | | | | | | | | | | | | | | | | |
| [symbol] | Composition | Y | Y | Y | Y | Y | Y | Y | Y | Y | Y | Y | Y | Y | Y | Y | Y |
| | shown | | | | | | | | | | | | | | | | |
| | in Table 3 | | | | | | | | | | | | | | | | |
| [symbol] layer | Layer | 70 nm | 70 nm | 70 nm | 70 nm | 70 nm | 70 nm | 70 nm | 70 nm | 70 nm | 70 nm | 70 nm | 70 nm | 70 nm | 70 nm | 70 nm | 70 nm |
| | thickness | | | | | | | | | | | | | | | | |

| | | | | | | | | | | | | | | | | |
|---|---|---|---|---|---|---|---|---|---|---|---|---|---|---|---|---|
| Temporary | 16KS40 | 16KS40 | 16KS40 | 16KS40 | 16KS40 | 16KS40 | 16KS40 | 16KS40 | 16KS40 | 16KS40 | [symbol] | [symbol] | 16KS40 | 16KS40 | 16KS40 | 16KS40 |
| support | | | | | | | | | | | | | | | | |
| Protective | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 |
| film | | | | | | | | | | | | | | | | |
| [symbol] layer | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- |
| | UP LDS | UP LDS | UP LDS | UP LDS | UP LDS | UP LDS | UP LDS | UP LDS | UP LDS | UP LDS | UP LDS | UP LDS | UP LDS | UP LDS | UP LDS | UP LDS |
| [symbol] of [symbol] layer | 95% | 95% | 95% | 95% | 95% | 95% | 95% | 95% | 95% | 95% | 95% | 95% | 95% | 95% | 95% | 95% |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | |
| [symbol] angle | 30° | 30° | 30° | 30° | 30° | 30° | 30° | 30° | 30° | 30° | 30° | 30° | 30° | 30° | 30° | 30° |
| [symbol] layer | N | N | N | N | N | N | N | N | N | N | N | N | N | N | N | N |

[symbol]

indicates data missing or illegible when filed

| | | | Example | Example | Example | Example | Example | Example | Example | Example | Example | Example | Example | Example | Example | Example | Example | Example |
|---|---|---|---|---|---|---|---|---|---|---|---|---|---|---|---|---|---|---|
| | | Type | 27 | 28 | 29 | 30 | 31 | 32 | 33 | 34 | 35 | 36 | 37 | 38 | 39 | 40 | 41 | 42 |
| [symbol] | [symbol] | B-1 | — | — | — | — | — | — | 160.0 | — | — | — | — | — | — | — | — | — |
| [symbol] | [symbol] | B-2 | — | — | — | — | — | — | — | 160.0 | — | — | — | — | — | — | — | — |
| | | B-3 | — | — | — | — | — | — | — | — | 160.0 | — | — | — | — | — | — | — |
| | | B-4 | 160.0 | 160.0 | 160.0 | 160.0 | 120.0 | 200.0 | — | — | — | 160.0 | 160.0 | 160.0 | 160.0 | 160.0 | 160.0 | 160.0 |
| | | B-5 | — | — | — | — | — | — | — | — | — | — | — | — | — | — | — | — |
| | | B-6 | — | — | — | — | — | — | — | — | — | — | — | — | — | — | — | — |
| | | B-7 | — | — | — | — | — | — | — | — | — | — | — | — | — | — | — | — |
| | | B-8 | — | — | — | — | — | — | — | — | — | — | — | — | — | — | — | — |
| | | B-9 | — | — | — | — | — | — | — | — | — | — | — | — | — | — | — | — |
| | | B-10 | — | — | — | — | — | — | — | — | — | — | — | — | — | — | — | — |
| | [symbol] | A- [symbol] -N | [symbol] .9 | [symbol] .9 | [symbol] .9 | [symbol] .9 | [symbol] .9 | [symbol] .9 | [symbol] .9 | [symbol] .9 | [symbol] .9 | [symbol] .9 | 13.0 | 12.0 | [symbol] .9 | [symbol] .9 | [symbol] .9 | [symbol] .9 |
| | com- | R [symbol] | [symbol] .9 | [symbol] .9 | [symbol] .9 | — | [symbol] .9 | [symbol] .9 | [symbol] .9 | [symbol] .9 | [symbol] .9 | [symbol] .9 | [symbol] | 6.0 | [symbol] .9 | [symbol] .9 | [symbol] .9 | [symbol] .9 |
| | pound | A-DCP | — | — | — | [symbol] .9 | — | — | — | — | — | — | — | — | — | — | — | — |
| | | [symbol] | 4.3 | 4.3 | 4.3 | 4.3 | 4.3 | 4.3 | 4.3 | 4.3 | 4.3 | 4.3 | 4.3 | 4.0 | 4.3 | 4.3 | 4.3 | 4.3 |
| | | A-DPH | 11.1 | 11.1 | 11.1 | 11.1 | 11.1 | 11.1 | 11.1 | 11.1 | 11.1 | 11.1 | 11.1 | 11.1 | 11.1 | 11.1 | 11.1 | 11.1 |
| | [symbol] | [symbol] | — | — | 0.72 | 0.72 | 0.72 | 0.72 | 0.72 | 0.72 | 0.72 | 0.72 | 0.72 | 0.72 | 0.72 | [symbol] | 1.50 | 0.72 |
| | [symbol] | [symbol] | — | — | — | — | — | — | — | — | — | — | — | — | — | — | — | — |
| | | [symbol] | — | — | — | — | — | — | — | — | — | — | — | — | — | — | — | — |
| | | [symbol] 907 | — | — | 1.00 | — | — | — | — | — | — | — | — | — | — | — | — | — |
| | | AP [symbol] | 1.00 | 1.00 | — | 1.00 | 1.00 | 1.00 | 1.00 | 1.00 | 1.00 | 1.00 | 1.00 | 1.00 | 1.00 | 1.00 | 1.00 | 1.00 |
| | Poly [symbol] | [symbol] | — | — | — | — | — | — | — | — | — | — | — | — | — | — | — | — |
| | in- | | | | | | | | | | | | | | | | | |
| | hibi- | [symbol] | 0.04 | 0.04 | 0.04 | 0.04 | 0.04 | 0.04 | 0.04 | 0.04 | 0.04 | 0.04 | 0.04 | 0.04 | 0.04 | 0.04 | 0.04 | 0.04 |
| | tor | [symbol] | 2.00 | 2.00 | 2.00 | 2.00 | 2.00 | 2.00 | 2.00 | 2.00 | 2.00 | 2.00 | 2.00 | 2.00 | 2.00 | 2.00 | 2.00 | 2.00 |
| | Addi- | [symbol] | — | — | — | — | — | — | — | — | — | — | — | — | 10.0 | — | — | — |
| | tive | [symbol] | | | | | | | | | | | | | | | | |
| | | [symbol] | — | — | — | — | — | — | — | — | — | — | — | — | — | 10.0 | — | — |
| | | [symbol] | | | | | | | | | | | | | | | | |
| | [symbol] | F- [symbol] 51A | 0.36 | 0.16 | 0.36 | 0.16 | 0.16 | 0.16 | 0.16 | 0.36 | 0.16 | 0.16 | 0.16 | 0.16 | 0.36 | 0.16 | 0.36 | 0.16 |
| | Sol- | 1- [symbol] | 300 | 300 | 300 | 300 | 300 | 300 | 300 | 300 | 300 | 300 | 300 | 300 | 300 | 300 | 300 | 300 |
| | vent | [symbol] | | | | | | | | | | | | | | | | |
| | | Methyl | 300 | 300 | 300 | 300 | 300 | 300 | 300 | 300 | 300 | 300 | 300 | 300 | 300 | 300 | 300 | 300 |
| | | [symbol] | | | | | | | | | | | | | | | | |
| | | Propy- | 100 | 100 | 100 | 100 | 100 | 100 | 100 | 100 | 100 | 100 | 100 | 100 | 100 | 100 | 100 | 100 |
| | | lene | | | | | | | | | | | | | | | | |
| | | glycol | | | | | | | | | | | | | | | | |
| | | mono- | | | | | | | | | | | | | | | | |
| | | methyl | | | | | | | | | | | | | | | | |
| | | ether | | | | | | | | | | | | | | | | |

| Layer thick- | | 3 μm | 3 μm | 3 μm | 3 μm | 3 μm | 3 μm | 3 μm | 3 μm | 3 μm | 3 μm | 3 μm | 3 μm | 3 μm | 3 μm | 3 μm | 3 μm |
|---|---|---|---|---|---|---|---|---|---|---|---|---|---|---|---|---|---|
| ness of [symbol] | | | | | | | | | | | | | | | | | |
| composition | | | | | | | | | | | | | | | | | |
| layer | | | | | | | | | | | | | | | | | |
| [symbol] | Composition | Y | Y | Y | Y | Y | Y | N | N | N | N | Y | Y | Y | Y | Y | Y |
| | shown | | | | | | | | | | | | | | | | |
| | in Table 3 | | | | | | | | | | | | | | | | |
| [symbol] layer | Layer | 70 nm | 70 nm | 70 nm | 70 nm | 70 nm | 70 nm | | | | | 70 nm | 70 nm | 70 nm | 70 nm | 70 nm | 70 nm |
| | thickness | | | | | | | | | | | | | | | | |

| | | | | | | | | | | | | | | | | |
|---|---|---|---|---|---|---|---|---|---|---|---|---|---|---|---|---|
| Temporary | 16KS40 | 16KS40 | 16KS40 | 16KS40 | 16KS40 | 16KS40 | 16KS40 | 16KS40 | 16KS40 | 16KS40 | [symbol] | 16KS40 | 16KS40 | 16KS40 | 16KS40 | 16KS40 |
| support | | | | | | | | | | | | | | | | |
| Protective | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 | 16KS40 |
| film | | | | | | | | | | | | | | | | |
| [symbol] layer | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- | LIGHT- |
| | UP LDS | UP LDS | UP LDS | UP LDS | UP LDS | UP LDS | UP LDS | UP LDS | UP LDS | UP LDS | UP LDS | UP LDS | UP LDS | UP LDS | UP LDS | UP LDS |
| [symbol] of [symbol] | 95% | 95% | 95% | 95% | 95% | 95% | 95% | 95% | 95% | 95% | 95% | 95% | 95% | 95% | 95% | 95% |
| layer | | | | | | | | | | | | | | | | |
| [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] | [symbol] |
| [symbol] | | | | | | | | | | | | | | | | |
| [symbol] angle | 30° | 30° | 30° | 30° | 30° | 30° | 30° | 30° | 30° | 30° | 30° | 30° | 30° | 30° | 30° | 30° |
| [symbol] layer | N | N | N | N | N | N | N | N | N | N | N | N | N | N | N | N |

[symbol]

indicates data missing or illegible when filed

Details of abbreviations shown in Table 4 or Table 5 other than those described above are shown below.

R-604: neopentyl glycol-modified trimethylolpropane diacrylate, KAYARD R-604, manufactured by Nippon Kayaku Co., Ltd.

A-DCP: tricyclodecane dimethanol diacrylate, manufactured by Shin-Nakamura Chemical Co., Ltd.

Irgacure OXE-02: photopolymerization initiator, manufactured by BASF SE

Irgacure OXE-03: photopolymerization initiator, manufactured by BASF SE

APi-307: photopolymerization initiator, Shenzhen UV-ChemTech Co., Ltd.DURANATE SBN-70D: hexamethylene diisocyanate-based blocked polyisocyanate, manufactured by Asahi Kasei Corporation

DURANATE MF-K60B: hexamethylene diisocyanate-based blocked polyisocyanate, manufactured by Asahi Kasei Corporation 16FB40: temporary support, polyethylene terephthalate film having a thickness of 16 μm (16FB40: product name, manufactured by Toray Industries, Inc.)

25KS40: temporary support, polyethylene terephthalate film having a thickness of 25 μm (25KS40: product name, manufactured by Toray Industries, Inc.)

From the results shown in Table 2, 4, and 5, it was found that the taper angle on the side surface of the patterned cured layer obtained in Examples 1 to 42, which was exposed to diffused light through the scattering layer, with respect to the surface direction of the base material was all 50° or less, and the gentle side surface was formed. In addition, in the obtained laminate, it was confirmed that occurrence of disconnection of the second transparent conductive portion formed on the surface of the patterned cured layer was suppressed.

Since the taper angle on the side surface of the cured layer with respect to the surface direction of the base material is 50° or less, in a case of being applied to the transparent conductive film, it can be expected that visibility due to reflection on the side surface of the contact hole is improved, and the transparent conductive film has a better appearance. Further, it can be expected that entrainment of air bubbles in a case of providing the transparent resin layer on the second transparent conductive portion by laminating is also suppressed.

### Example 43

Sample preparation and various evaluations were performed in the same manner as in Example 22, except that, in Example 22, the binder polymer solution: B-1 was changed to B-11. Each of the various evaluations had the same results as in Example 22.

### Example 44

Sample preparation and various evaluations were performed in the same manner as in Example 27, except that, in Example 27, the binder polymer solution: B-4 was changed to B-11. Each of the various evaluations had the same results as in Example 27.

### Example 51

In the same manner as in Example 1, a conductive substrate having a transparent film and a patterned transparent conductive portion on a transparent base material was obtained.

The above-described conductive substrate was slit-coated with the photosensitive composition used in Example 1 so that a film thickness after drying was 5 μm, and then dried.

The photosensitive composition layer was patterned in the same manner as in Example 1 to obtain a laminate having a patterned cured layer, and in a case where various evaluations were performed, the same results as in Example 1 were obtained.

### Comparative Example 2

A laminate having the patterned cured layer was obtained in the same manner as in Example 51, except that the pattern exposure was performed without the scattering layer, and then various evaluations were performed. The results of the various evaluations were the same as those of Comparative Example 1.

### Example 52

A patterned laminate was obtained in the same manner as in Example 51, except that the scattering layer was changed to the scattering layer used in Example 2. The results of the various evaluations were the same as those of Example 2.

### Examples 53 to 60

A laminate having the patterned cured layer was obtained in the same manner as in Example 51, except that the scattering layer was manufactured from the following, and various evaluations were performed. The results of the various evaluations were the same as those of Examples 3 to 10. Specifically, for example, the evaluation results of Example 53 were the same results as the evaluation results corresponding to Example 3, and the evaluation results of Example 60 were the same results as the evaluation results corresponding to Example 10.

Example 53: LSD60ACUVT30 (manufactured by OPTICAL SOLUTIONS, scattering angle: 60°, material: UV transparent acrylic resin, resin layer having irregularities, thickness: 760 μm)

Example 54: LIGHT-UP LDS (manufactured by KIMOTO, scattering angle: 30°, light diffusion polymer film, resin layer having irregularities, thickness: 115 μm)

Example 55: LIGHT-UP GM7 (manufactured by KIMOTO, scattering angle: 15°, light diffusion polymer film, resin layer having irregularities, thickness: 115 μm)

Example 56: LIGHT-UP MXE (manufactured by KIMOTO, scattering angle: 30°, light diffusion polymer film, resin layer having irregularities, thickness: 115 μm)

Example 57: SDXK-1FS (manufactured by SUNTECHOPT, scattering angle: 15°, light diffusion polymer film, resin layer having irregularities, thickness: 39 μm)

Example 58: HAA120 (manufactured by LINTEC Corporation, scattering angle: 25°, light diffusion polymer film, resin layer having refractive index distribution structure, thickness: 120 μm)

Example 59: Opalus PBS-689G (manufactured by KEIWA Inc., scattering angle: 30°, particles-containing light diffusion polymer film, specific particles-containing layer, thickness: 83 μm)

Example 60: Opalus UDD-247D2 (manufactured by KEIWA Inc., scattering angle: 30°, light diffusion polymer film, resin layer having irregularities, thickness: 51 μm)

### Example 101

Using the laminates obtained in Examples 1 to 44 and Examples 51 to 60, a touch panel was produced by a known method. The produced touch panel was attached to a liquid crystal display element produced by a method described in paragraphs 0097 to 0119 of JP2009-47936A, thereby producing a liquid crystal display device equipped with a touch panel.

It was confirmed that the liquid crystal display device equipped with a touch panel had excellent display properties and operated without problems.

### EXPLANATION OF REFERENCES

10: transparent conductive film
12: base material
14: first transparent conductive portion
16: photosensitive composition layer
16A: patterned cured layer
18: second transparent conductive portion
20: transparent resin layer
22: contact hole
24: temporary support
26: exposure mask
26A: light shielding region of exposure mask
28: scattering layer
30: transparent conductive film in related art
32: scattering exposure mask
32A: light shielding region of scattering exposure mask
34: scattering temporary support

The disclosure of Japanese Patent Application No. 2020-098776 filed on Jun. 5, 2020 and the disclosure of Japanese Patent Application No. 2020-121631 filed on Jul. 15, 2020 are incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A method for producing a laminate, comprising:
a step 1 of preparing a laminate precursor having a base material, a first transparent conductive portion, and a photosensitive composition layer in this order;
a step 2 of pattern-exposing the photosensitive composition layer with scattered light from a side of the photosensitive composition layer opposite to a side on which the base material is provided; and
a step 3 of developing the pattern-exposed photosensitive composition layer to form a patterned cured layer.

2. The method for producing a laminate according to claim 1,
wherein the step 1 is a step of forming the photosensitive composition layer on a side of the first transparent conductive portion in a conductive substrate which has the base material and the first transparent conductive portion disposed on the base material, and
the step 2 is a step of performing a pattern exposure by irradiating through an exposure mask, the photosensitive composition layer with scattered light from an exposure light source disposed on the side of the photosensitive composition layer opposite to the side on which the base material is provided.

3. The method for producing a laminate according to claim 1,
wherein the laminate comprises the base material, the first transparent conductive portion, and the patterned cured layer in this order, and
wherein a taper angle of a wall surface of a portion having the patterned cured layer with respect to a surface direction of the base material is 35° or less.

4. The method for producing a laminate according to claim 1,
wherein, in the step 2, a scattering layer having a diffuse transmittance of 5% or more and an exposure light source are arranged on the side of the photosensitive composition layer opposite to the side on which the base material is provided, and
the scattered light is irradiated from the exposure light source through the scattering layer.

5. The method for producing a laminate according to claim 4,
wherein a scattering angle of the scattering layer is 20° or more.

6. The method for producing a laminate according to claim 1,
wherein, in the step 2, on the side of the photosensitive composition layer opposite to the side on which the base material is provided, an exposure mask, a scattering layer having a diffuse transmittance of 5% or more, and an exposure light source are provided in this order from the photosensitive composition layer side.

7. The method for producing a laminate according to claim 1,
wherein, in the step 2, on the side of the photosensitive composition layer opposite to the side on which the base material is provided, a scattering layer having a diffuse transmittance of 5% or more, an exposure mask, and an exposure light source are provided in this order from the photosensitive composition layer side.

8. The method for producing a laminate according to claim 4,
wherein the scattering layer contains a matrix material and particles present in the matrix material, and
a difference in refractive index between the matrix material and the particles is 0.05 or more.

9. The method for producing a laminate according to claim 4,
wherein the scattering layer contains a matrix material and particles present in the matrix material, and
an average primary particle diameter of the particles is 0.3 μm or more.

10. The method for producing a laminate according to claim 4,
wherein the scattering layer has irregularities on at least one surface.

11. The method for producing a laminate according to claim 10,
wherein the irregularities have a plurality of convex portions, and
a distance between top portions of convex portions adjacent to each other is 10 μm to 50 μm.

12. The method for producing a laminate according to claim 4,
wherein the scattering layer and the exposure mask are arranged at a position where the scattering layer and the exposure mask do not come into contact with each other.

13. The method for producing a laminate according to claim 4,
wherein the scattering layer and the exposure mask are arranged in contact with each other.

14. The method for producing a laminate according to claim 1,
wherein an exposure mask is a scattering exposure mask having a diffuse transmittance of 5% or more.

15. The method for producing a laminate according to claim 1,
wherein the step 1 includes forming the photosensitive composition layer using a transfer material which has a temporary support and at least one photosensitive composition layer disposed on the temporary support.

16. The method for producing a laminate according to claim 15,
wherein the temporary support is a temporary support having a diffuse transmittance of 5% or more.

17. The method for producing a laminate according to claim 15,
wherein the pattern exposure in the step 2 is a contact exposure in which an exposure mask is brought into contact with the temporary support for exposure.

18. The method for producing a laminate according to claim 15,
wherein the transfer material further has a scattering layer having a diffuse transmittance of 5% or more between the temporary support and the photosensitive composition layer, and
in the transfer, the photosensitive composition layer and the scattering layer are transferred.

19. The method for producing a laminate according to claim 1, further comprising, after the step 3:
a step 4 of forming a second transparent conductive portion on the patterned cured layer.

20. A touch panel sensor comprising, in the following order:
a base material;
a first transparent conductive portion;
a cured layer having a contact hole; and
a second transparent conductive portion,
wherein a taper angle of the contact hole in the cured layer with respect to a surface direction of the base material in a cross section parallel to a normal direction of the base material is 50° or less.

21. A touch panel sensor according to claim 20, wherein the taper angle is 35° or less.
